(19) United States
(12) Patent Application Publication
(10) Pub. No.: US 2025/0259852 A1
(43) Pub. Date: Aug. 14, 2025

(54) TOOL AND PROCESSES FOR ELECTROCHEMICAL ETCHING

(71) Applicant: Board of Regents, The University of Texas System, Austin, TX (US)

(72) Inventors: Sidlgata V. Sreenivasan, Austin, TX (US); Paras Ajay, Austin, TX (US); John G. Ekerdt, Austin, TX (US); Crystal Barrera, Austin, TX (US); Akhila Mallavarapu, Philadelphia, PA (US); Mark Hrdy, Austin, TX (US); Parth Pandya, Austin, TX (US)

(21) Appl. No.: 18/854,433

(22) PCT Filed: Apr. 6, 2023
(86) PCT No.: PCT/US2023/017725

§ 371 Date: Oct. 4, 2024

Related U.S. Application Data
(60) Provisional application No. 63/328,510, filed on Apr. 7, 2022.
(60) Provisional application No. 63/343,003, filed on May 17, 2022.
(60) Provisional application No. 63/342,699, filed on May 17, 2022.
(60) Provisional application No. 63/342,717, filed on May 17, 2022.
(60) Provisional application No. 63/349,946, filed on Jun. 7, 2022.

(51) Int. Cl. H01L 21/308

(52) U.S. Cl. CPC H01L 21/308

(57) ABSTRACT

A method for fabricating high aspect ratio nanostructures in arbitrary functional materials. An (N+1)^{th} layer of substrate material is deposited on top of existing N layers of nanostructures, where N is a natural number. The substrate material in the (N+1)^{th} layer is then patterned and etched to create complementary nanostructures in the substrate material. Furthermore, a conformal coating of gap-fill materials, encapsulation layers, and functional material on the complementary nanostructures is performed to create functional material nanostructures in the (N+1)^{th} layer. A set of selective etches on the substrate material is then performed leaving behind multi-layered high aspect ratio nanostructures in the functional material.

### TECHNICAL FIELD

The present invention relates generally to electrochemical etching, and more particularly to creating arbitrary high aspect ratio nanostructures in a variety of substrates.

### BACKGROUND

Electrochemical etching is a type of etching technique used to transfer information on the substrate material, conductive metals, etc. using the simple principle of electrolysis. Electrochemical etching is also a marking method that etches a perfectly high contrast, permanent mark into any material that conducts electricity. It does not heat up the material and does not weaken or alter the microstructure of the material.

Electrochemical etching is a process that is extremely fast and considerably cheaper than other marking methods. It is known for bringing out great details accompanied by a fast batch setup. These characteristics make it a common marking method for medical instruments, aircraft parts, tools, cutlery and so on.

Unfortunately, the tools and processes for electrochemical etching are currently deficient in creating arbitrary high aspect ratio nanostructures in a variety of substrates, such as silicon, aluminum oxide, etc.

### SUMMARY

In one embodiment of the present disclosure, a method for fabricating high aspect ratio nanostructures in arbitrary functional materials comprises depositing an (N+1)^{th} layer of substrate material on top of existing N layers of nanostructures, where N is a natural number. The method further comprises patterning and etching in the (N+1)^{th} layer of the substrate material to create complementary nanostructures in the substrate material. The method additionally comprises performing a conformal coating of gap-fill materials, encapsulation layers, and functional material on the complementary nanostructures to create functional material nanostructures in the (N+1)^{th} layer. Furthermore, the method comprises performing a set of selective etches on the substrate material leaving behind multi-layered high aspect ratio nanostructures in the functional material.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIGS. 1A-1B illustrate exemplary nanostructures formed in Anodic Aluminum Oxide (AAO) using exemplary anodization processes in accordance with an embodiment of the present disclosure;

FIG. 2 is a flowchart of a method for performing the Atomically precise Electrochemical Etching (AE2) process in accordance with an embodiment of the present disclosure;

FIGS. 3A-3F depict the cross-sectional views for performing the AE2 process using the steps described in FIG. 2 in accordance with an embodiment of the present disclosure;

FIG. 4 illustrates an exemplary roll-to-roll (R2R) AE2 process in accordance with an embodiment of the present disclosure;

FIGS. 5A-5B illustrate an exemplary design for side-to-side etchant flow in accordance with an embodiment of the present disclosure;

FIG. 6 illustrates an exemplary design for the etchant introduction and exit over the entire area of the process substrate in accordance with an embodiment of the present disclosure;

FIGS. 7A-7B illustrate an exemplary spin-spray-type etchant flow system with an eccentrically rotating etchant spray arm and passive gravity-driven etchant outflow in accordance with an embodiment of the present disclosure;

FIG. 8 illustrates an exemplary design with a sliding etch zone in accordance with an embodiment of the present disclosure;

FIGS. 9A and 9B illustrate an exemplary double-axis, double-arm assembly for etchant agitation in accordance with an embodiment of the present disclosure;

FIG. 10 illustrates an entire etchant flow assembly, with the process chamber, mixing chamber, precursor storage, pump assemblies, and etchant and precursor state sensing and actuation mechanisms, in accordance with an embodiment of the present disclosure;

FIG. 11 illustrates the vacuum-based degassing strategy in accordance with an embodiment of the present disclosure;

FIGS. 12A-12D illustrate exemplary etchant freezing-based reaction quenching in accordance with an embodiment of the present disclosure;

FIGS. 13A-13D illustrate etchant freezing and sublimation-based reaction quenching in accordance with an embodiment of the present disclosure;

FIG. 14 illustrates an exemplary design for thermal compensation during reaction quenching and starting in accordance with an embodiment of the present disclosure;

FIGS. 15A-15B illustrate an exemplary in-situ metrology system with total substrate coverage in accordance with an embodiment of the present disclosure;

FIG. 16 illustrates an exemplary in-situ metrology system with scannable optics in accordance with an embodiment of the present disclosure;

FIG. 17 illustrates an exemplary system for Digital Micromirror Device (DMD)-modulated substrate thermal control in accordance with an embodiment of the present disclosure;

FIG. 18 illustrates the cross-section of the AE2 tool for electric field control in accordance with an embodiment of the present disclosure;

FIGS. 19A-19B illustrate an exemplary edge contact design showing frontside seals that make contact on the outside edge of the process substrate in accordance with an embodiment of the present disclosure;

FIG. 20 illustrates an exemplary backside contact with backside fluid in accordance with an embodiment of the present disclosure;

FIG. 21 illustrates an exemplary backside contact using a vacuum chuck in accordance with an embodiment of the present disclosure;

FIG. 22 is a flowchart of a method for the formation of nanowires of functional material in accordance with an embodiment of the present disclosure;

FIGS. 23A-23C depict the cross-sectional views for the formation of nanowires of functional material using the steps described in FIG. 22 in accordance with an embodiment of the present disclosure;

FIGS. 24A-24C depict the cross-sectional views of the functional material during the process of forming nanowires of functional material in accordance with an embodiment of the present disclosure;

FIG. 25 is a flowchart of a method for forming nanowires of a functional material (e.g., boron) in accordance with an embodiment of the present disclosure;

FIGS. 26A-26C depict the various versions of the final structure that result from utilizing the method of FIG. 25 in accordance with an embodiment of the present disclosure;

FIGS. 27A-27C depict the cross-sectional views of the final structures of FIGS. 26A-26C, respectively, in accordance with an embodiment of the present disclosure;

FIG. 28 is a flowchart of a method for forming nanowires of functional material in accordance with an embodiment of the present disclosure;

FIG. 29A illustrates the final structure using the method of FIG. 28 when the pulse anodization techniques are not utilized in accordance with an embodiment of the present disclosure;

FIG. 29B illustrates the final structure using the method of FIG. 28 when pulse anodization techniques are utilized in accordance with an embodiment of the present disclosure;

FIGS. 30A-30B illustrate a diagram for collapse prevention and/or un-collapsing collapsed nanostructures in accordance with an embodiment of the present disclosure;

FIG. 31 is a flowchart of a method for forming nanowires of boron (or any other functional material) in accordance with an embodiment of the present disclosure;

FIGS. 32A-32D depict cross-sectional views for forming nanowires of boron (or any other functional material) using the steps described in FIG. 31 in accordance with an embodiment of the present disclosure;

FIG. 33 is a flowchart of a method for fabricating silicon and polycrystalline silicon structures using MACE and a metal break technique in accordance with an embodiment of the present disclosure;

FIGS. 34A-34D depict the cross-sectional views for fabricating silicon and polycrystalline silicon structures using MACE and a metal break technique using the steps described in FIG. 33 in accordance with an embodiment of the present disclosure;

FIG. 35A is an SEM (scale bar is 200 nm) image of the cross-section of the polysilicon pillars in accordance with an embodiment of the present disclosure;

FIG. 35B is an SEM image (scale bar is 1 micrometer) of the tilted cross-section of the polysilicon pillars in accordance with an embodiment of the present disclosure;

FIG. 36 is a flowchart of a method for creating an imprint template of inverse tone in accordance with an embodiment of the present disclosure;

FIGS. 37A-37C depict the cross-sectional views for creating an imprint template of inverse tone using the steps described in FIG. 36 in accordance with an embodiment of the present disclosure;

FIG. 38A is an SEM image (scale bar of 200 nm) of the cross-section of the polysilicon pillars with approximately 170 nm spacing in accordance with an embodiment of the present disclosure;

FIG. 38B is an SEM image (scale bar of 200 nm) of the cross-section of the polysilicon pillars with approximately 30 nm spacing after removal of the resist caps in accordance with an embodiment of the present disclosure;

FIG. 39A illustrates a cross-sectional SEM image (scale bar of 400 nm) of the polysilicon diamond pillars fabricated using MACE using the steps of FIG. 36 in accordance with an embodiment of the present disclosure;

FIG. 39B illustrates a top down SEM image (scale bar of 500 nm) of the polysilicon diamond pillars fabricated using MACE using the steps of FIG. 36 in accordance with an embodiment of the present disclosure;

FIG. 39C illustrates a top down SEM image (scale bar of 100 nm) of the polysilicon diamond pillars fabricated using MACE using the steps of FIG. 36 in accordance with an embodiment of the present disclosure;

FIG. 40 is a cross-section SEM (scale bar of 800 nm) of fins etched past the polysilicon film interface with silicon in accordance with an embodiment of the present disclosure;

FIG. 41 illustrates mitigating disturbances in a residual layer in accordance with an embodiment of the present disclosure;

FIG. 42 illustrates an in-situ monitoring and control process in accordance with an embodiment of the present disclosure;

FIG. 43A illustrates an exemplary AE2 process in accordance with an embodiment of the present disclosure;

FIG. 43B illustrates a holey carrier in accordance with an embodiment of the present disclosure;

FIG. 44 is a flowchart of a method for the creation of functional material high aspect ratio nanostructures with tethers for stability in accordance with an embodiment of the present disclosure;

FIGS. 45A-45E depict the cross-sectional views for the creation of functional material high aspect ratio nanostructures with tethers for stability using the steps described in FIG. 44 in accordance with an embodiment of the present disclosure;

FIG. 46 is a flowchart of an alternative method for the creation of functional material high aspect ratio nanostructures with tethers for stability in accordance with an embodiment of the present disclosure;

FIGS. 47A-47G depict the cross-sectional views for the creation of functional material high aspect ratio nanostructures with tethers for stability using the steps described in FIG. 46 in accordance with an embodiment of the present disclosure;

FIG. 48 illustrates a method for an RIE-based process for the creation of functional material nanostructures in accordance with an embodiment of the present disclosure;

FIG. 49 is a flowchart of a method for creating functional material nanostructures using CVD-based hole-filling in accordance with an embodiment of the present disclosure;

FIG. 50 is a flowchart of a method for creating functional material nanostructures using ALD-based hole filling in accordance with an embodiment of the present disclosure;

FIG. 51 is a flowchart of a method for spin-coating of functional material containing polymer for hole filling in accordance with an embodiment of the present disclosure;

FIG. 52 is a flowchart of a method for a confined/templated VLS/VS functional material growth in accordance with an embodiment of the present disclosure; and

FIG. 53 is a flowchart of a method for a multi-tier process in accordance with an embodiment of the present disclosure.

### DETAILED DESCRIPTION

As stated in the Background section, electrochemical etching is a type of etching technique used to transfer information on the substrate material, conductive metals, etc. using the simple principle of electrolysis. Electrochemical etching is also a marking method that etches a perfectly high contrast, permanent mark into any material that conducts electricity. It does not heat up the material and does not weaken or alter the microstructure of the material.

Electrochemical etching is a process that is extremely fast and considerably cheaper than other marking methods. It is known for bringing out great details accompanied by a fast batch setup. These characteristics make it a common marking method for medical instruments, aircraft parts, tools, cutlery and so on.

Unfortunately, the tools and processes for electrochemical etching are currently deficient in creating arbitrary high aspect ratio nanostructures in a variety of substrates, such as silicon, aluminum oxide, etc.

The embodiments of the present disclosure provide tools and processes for utilizing electrochemical etching in creating arbitrary high aspect ratio nanostructures in a variety of substrates, such as silicon, aluminum oxide, etc. as discussed below.

The following describes tools and processes for the Atomically precise Electrochemical Etching (AE2) process. AE2 can be used to create arbitrary high aspect ratio nanostructures in a variety of substrates including silicon, aluminum oxide, etc.

AE2 includes methods to create such nanostructures in silicon (and other substrates) using the catalyst influenced chemical etching (CICE) process (also referred to as metal assisted chemical etching (MACE), MacEtch, AToMM).

AE2 can also be used to create nanostructures in valve-metal oxides (valve-metals include Al, Mg, Zr, Nb, Sn, Hf, Ta, W, Bi, etc.). Such nanostructures are created using electrochemical etching (or anodization) of the valve-metal films. Details regarding reaction regimes for the creation of nanostructures in valve-metal oxides are discussed in Lee at al., “Porous Anodic Aluminum Oxide: Anodization and Templated Synthesis of Functional Nanostructures,” Chemical Reviews, Vol. 114, No. 15, 2014, pp. 7487-7556, which is hereby incorporated by reference herein in its entirety. As discussed further below, anodized valve-metal oxides is referred to as AVO (Anodic Valve-metal Oxide). In one embodiment, Anodic Aluminum Oxide (AAO) is an exemplar AVO. In general, AVOs with deep nanostructured pores are formed in acidic electrolytes (these are alternatively referred to as etchants), such as selenic, sulfuric, oxalic, phosphoric, chromic, malonic, tartaric, citric, malic acid, etc., in which anodic oxide is slightly soluble. AVO nanostructures can be formed at both potentiostatic and galvanostatic conditions. Current density (j) in pore-forming anodization under potentiostatic conditions remains almost constant within a certain range of values during the anodization process. The thickness of the resulting porous oxide film is linearly proportional to the total amount of charge (i.e., anodization time, t) involved in the electrochemical reaction

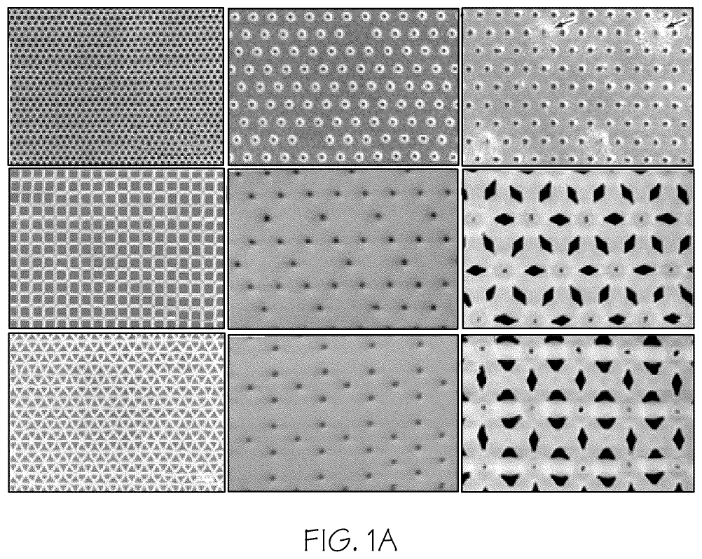

FIGS. 1A-1B illustrate exemplary nanostructures formed in AAO using exemplary anodization processes in accordance with an embodiment of the present disclosure.

Referring to FIGS. 1A-1B, FIG. 1A illustrates the top views of the nanostructures formed in AAO; whereas, FIG. 1B illustrates the side view of distinct nanostructures.

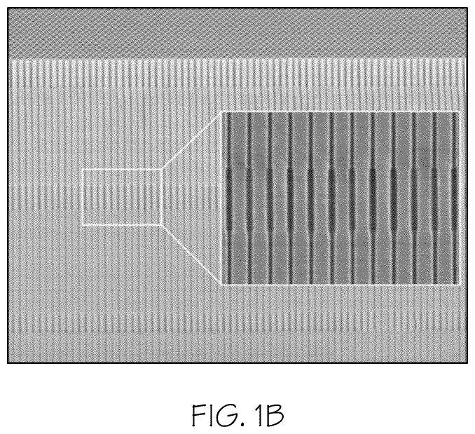

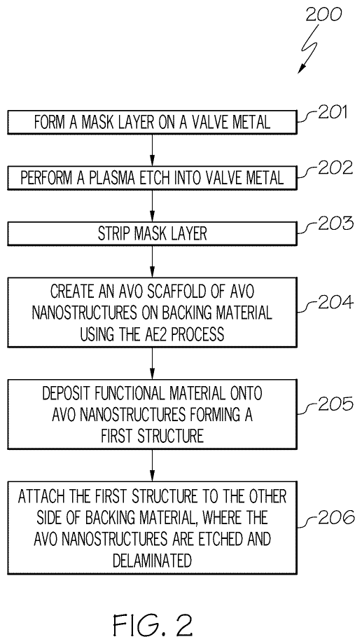

Referring now to FIG. 2, FIG. 2 is a flowchart of a method 200 for performing the AE2 process in accordance with an embodiment of the present disclosure. FIGS. 3A-3F depict the cross-sectional views for performing the AE2 process using the steps described in FIG. 2 in accordance with an embodiment of the present disclosure.

Referring to FIG. 2, in conjunction with FIGS. 3A-3F, in step 201, a mask layer 301 is formed on a valve metal 302 (e.g., aluminum), which optionally resides on backing material 303 as shown in FIG. 3A. In one embodiment, mask layer 301 corresponds to carbon pillars as shown in FIG. 3A. In one embodiment, such carbon pillars are created by depositing resist using nanoimprint lithography followed by a plasma etch.

In step 202, a plasma etch into valve metal 302 is performed as shown in FIG. 3B. For example, in the embodiment in which value metal 302 includes aluminum, the aluminum can be etched using chlorine-based plasmas.

In step 203, mask layer 301 is stripped as shown in FIG. 3C.

In step 204, in one embodiment, an AVO scaffold 305 of AVO nanostructures 304 is created on backing material 303 (which is optional) using the AE2 process as shown in FIG. 3D. An exemplary hole morphology of AVO scaffold 305 is also shown in FIG. 3D. In one embodiment, backing material 303 is aluminum in roll form.

In step 205, functional material 306 is optionally deposited onto AVO nanostructures 304 (which optionally includes arrays of holes as shown in element 305) as shown in FIG. 3E.

In step 206, the structure of FIG. 3E is optionally attached to the other side of backing material (final backing material) 303, where AVO nanostructures 304 are etched and delaminated as shown in FIG. 3F. For example, in one embodiment, etchants, such as NaOH, KOH, H₃PO₄, and HF, may be utilized for etching and delaminating AVO nanostructures 304 as shown in FIG. 3F.

As previously discussed, FIGS. 2 and 3A-3F illustrate an exemplary AE2 process. Optional collapse prevention of nanostructures 304 in the functional material (once the AVO scaffold 305 has been removed) could be performed using one or more of the following techniques. In a first technique, a first metal is deposited at the base of scaffold 305, followed by an insulator, followed by the functional material (e.g., functional material 306). The deposition could be performed using atomic layer deposition (ALD), chemical vapor deposition (CVD), low pressure CVD (LPCVD), atmospheric pressure CVD (APCVD), physical vapor deposition (PVD), electrochemical deposition, etc. In one embodiment, the metal insulator layer is used to create electrostatic repulsion between the free-standing nanostructures in the functional material.

In a second technique, a first partial etch of the AVO (e.g., AVO scaffold 305) followed by depositing one or more supporting materials (that are resistant to an AVO etchant) around the exposed portions of the functional material nanostructures 304 using ALD, CVD, LPCVD, APCVD, PVD, electrochemical deposition techniques, etc. is performed. AVO nanostructures 304 are then removed using an AVO etchant.

In a third technique, a first partial etch of the AVO (e.g., AVO scaffold 305) and leaving the AVO as the supporting material for the functional material nanostructures 304 is performed.

In one embodiment, the walls of nanostructures 304 created in the AVO have a predefined taper. In one embodiment, the taper is continuous. In another embodiment, the taper is in steps. In one embodiment, the continuous taper is created by changing the current (at potentiostatic conditions) and/or voltage (at galvanostatic conditions). In one embodiment, such a change is gradual. In another embodiment, such a change is monotonic. In one embodiment, the taper is produced in such a manner as to aid in the gap-free deposition of functional materials in the AVO nanostructures 304.

In one embodiment, high aspect ratio holes are created in valve metal 302. In one embodiment. a seed pattern is first created on the surface of valve metal 302. In one embodiment, the seed pattern is created using a combination of nanoimprint lithography and etching (which could be a wet or dry etch). Subsequently, valve metal 302 is anodized in the pore formation regime, where the time of the etch governs the depth of the holes. In one embodiment, the holes are tapered. In one embodiment, the taper is continuous. In another embodiment, the taper is in steps. In one embodiment, the taper is monotonic. In one embodiment, valve metal 302 is aluminum. In one embodiment, a functional material (e.g., functional material 306) is deposited post anodization into the high aspect ratio holes. In one embodiment, the deposition is performed using CVD, PECVD, LPCVD, APCVD, ALD, PVD, electrochemical deposition, etc.

In one embodiment, a functional material is deposited/grown/filled post-anodization into the high aspect ratio holes. In one embodiment, the deposition/growth/filling is performed using CVD, PECVD, LPCVD, APCVD, ALD, PVD, electrochemical deposition, electroplating, electroless plating, electrochemical ALD, etc.

In one embodiment, post-anodization, a barrier material is deposited conformally to protect the functional material (from oxidation, for instance). Exemplary barrier materials include, but not limited to, silicon, silicon dioxide, silicon nitride, silicon carbide, carbon, metals, platinum, gold, ruthenium, polymers, etc. In one embodiment, for electroplating, a seed layer is subsequently deposited in a conformal manner. In one embodiment, the conformal seed layer is connected to an electrode (for instance, on a side of the substrate). Additives, such as polyethylene glycol (PEG), are utilized to promote bottom-up growth of functional material, and to reduce the likelihood of void formation during deposition.

Alternatively, a bi-layer stack of a valve metal (that is distinct from aluminum) and aluminum is utilized during anodization. It is known that anodic aluminum oxide (AAO) formed on a valve metal that is distinct from aluminum (such as Ti, W, Nb, Zr, Ta, etc.) contains a valve metal oxide at the bottom of the etched structure (that is distinct from aluminum oxide). In one embodiment, the valve metal oxide is subsequently selectively removed (relative to aluminum oxide) using a suitable wet etch process. Subsequently, in one embodiment, an area-selective atomic layer deposition (ALD) process is utilized to coat a barrier layer only on the sides of the etched holes and not the bottom, where the exposed valve metal is present. For instance, with tungsten as the valve metal above, an area-selective process for SiO₂ exists that would selectively coat on Al₂O₃ and not the tungsten. The un-coated tungsten could subsequently be used as the seed layer to electroplate a functional material in a void-free manner. Alternatively, instead of area-selective ALD of the barrier layer, a conformal coating of the barrier layer is performed, followed by etching off the base of the conformal barrier coating (using reactive ion etching, for instance) to open up the valve metal layer (that was previously buried underneath the conformal barrier layer). The un-coated valve metal layer could subsequently be used as the seed layer to electroplate a functional material in a void-free manner. After removal of the AAO scaffold, and the valve metal, a last barrier layer deposition is performed to cover the bottom of the functional material.

In general, in one embodiment, the seed layer for electroplating is one or more of the following: gold, bismuth, cadmium, copper, lead, antimony, tellurium, and zinc, silver, beryllium, cobalt, chromium, iron, molybdenum, niobium, palladium, platinum, tantalum, thorium, titanium, vanadium, tungsten, and zirconium.

In one embodiment, hole tapering is utilized to reduce electroplating void formation tendency. In one embodiment, electroplating is performed in a roll-to-roll manner.

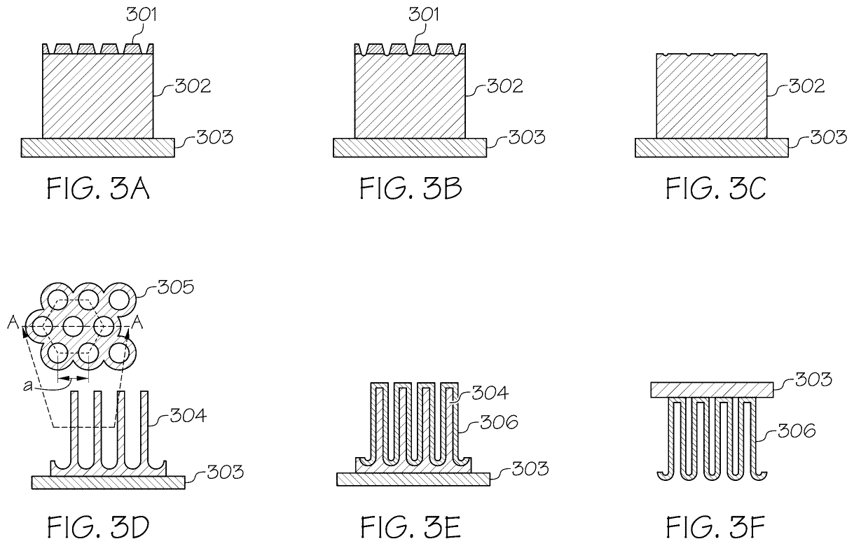

Referring now to FIG. 4, FIG. 4 illustrates an exemplary roll-to-roll (R2R) AE2 process in accordance with an embodiment of the present disclosure.

As shown in FIG. 4, FIG. 4 illustrates a nanoimprint lithography (NIL) template roll 401 as well as a source substrate roll 402. Furthermore, FIG. 4 illustrates an optional roll-to-roll (R2R) nanoimprint lithography (NIL) 403.

Additionally, FIG. 4 illustrates a magnified view of the template (see element 404) and an optional R2R reactive ion etching (RIE)/descum etch 405. Furthermore, FIG. 4 illustrates R2R AE2 406 with an optional taper in the nanostructures to enable a subsequent optional high aspect ratio chemical vapor deposition (CVD) step.

Furthermore, FIG. 4 illustrates an optional R2R deposition 407, an optional in-situ functional metrology 408 and an optional transfer to the final roll 409.

The AE2 process can be used to fabricate novel devices including DRAM, NAND Flash, SRAM, FinFETs, DLD (Deterministic Lateral Displacement) devices, supercapacitors, etc.

In one embodiment, a tool for the AE2 process has the following objective—etching nanoscale features using the AE2 process at (or above) a target yield and at (or above) a target throughput. In one embodiment, the tool is optimized specifically for AVO nanopore creation.

Achieving a target yield requires the etch height variation to be below a certain fraction of the etch height (for instance, 30% in one embodiment, 20%, 10%, 5%, or lower in other embodiments). Achieving this objective requires several sub-systems and capabilities, including but not limited to, the ability to handle corrosive AE2 etchants, while not leaching contaminants (metal or otherwise). Inert polymers, such as polytetrafluoroethylene (PTFE), perfluoroalkoxy alkane (PFA), high-density polyethylene (HDPE), etc. satisfy such a requirement.

Furthermore, in one embodiment, achieving the objective discussed above requires several sub-systems and capabilities, including the ability to handle 300 mm or larger substrate sizes. This requires automated loading and unloading of 300 mm substrates, between internal chambers of the tool, and between internal chambers and input/output ports of the tool. Additionally, this also requires tool chambers that are sized to handle 300 mm substrates. Automated substrate handling and tool machining solutions that satisfy these requirements are available. In one embodiment, the process substrate is processed in a vertical configuration, but once the etch is performed, the substrate is swiveled to a horizontal configuration to be handled using, for instance, a selective compliance assembly robot arm (SCARA)-type robot arm. In one embodiment, the AE2 process is performed on roll-to-roll substrates. In subsequent designs, the wafer and/or substrate is replaced with a roll substrate. In one embodiment, the roll substrate is processed in a step and repeat manner, where the roll is processed at the current location, then the chamber unsealed, the roll stepped to a new location, the chamber sealed again, and processing is performed on the new location (and so on). In another embodiment, the roll substrate is processed in a continuous manner. In one embodiment, the seal between the roll substrate and the etch chamber is a sliding seal.

Additionally, in one embodiment, achieving the objective discussed above requires several sub-systems and capabilities, including frontside etchant control. On the side of the process substrate where the AE2 process takes place, reactants for the AE2 process need to be maintained at a uniform concentration throughout the extent of the process substrate, while also ensuring products of the AE2 process are continuously removed from the reaction site. Uniform reactant concentration can be maintained by continuous or intermittent etchant circulation, using design features that improve etchant uniformity, and using in-chamber etchant agitation methods that prevent regions of etchant stagnation.

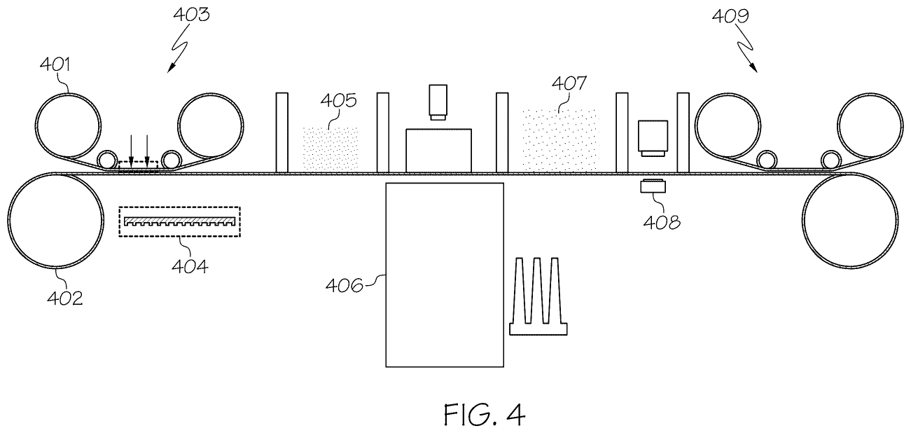

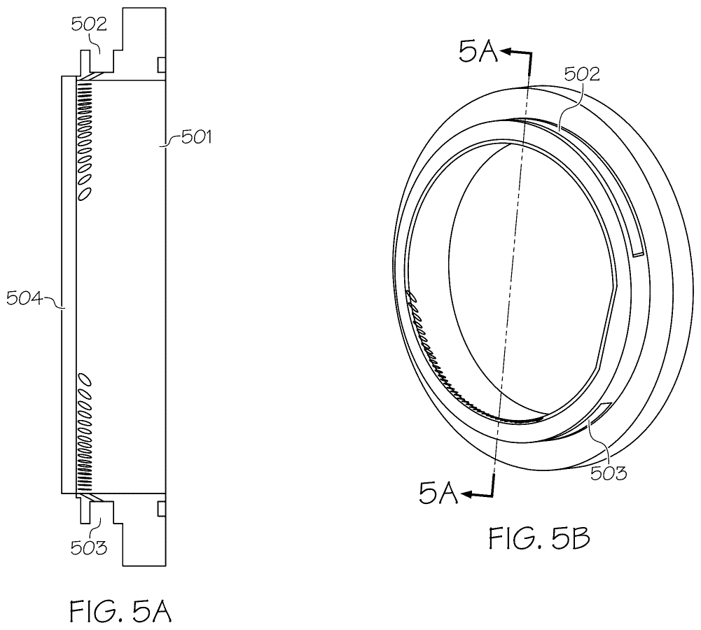

In one embodiment, etchant circulation can be achieved by several methods. If a peripheral contact is used in the frontside chamber for etchant containment (assuming this is the side where AE2 process takes place), groups of one or more inlet ports (which could be in the form of nozzles) could be used to introduce etchant into the chamber, and a group of one or more outlet ports could be used to take etchant out of the chamber. In one embodiment, the group of inlet ports and outlet ports are integrally fabricated with the frontside chamber. In one embodiment, Computational Fluid Dynamics (CFD) based fluidic simulations along with design optimization techniques are used to ensure minimization of flow non-uniformities and stagnation. FIGS. 5A-5B and 6 illustrate two exemplary designs.

FIGS. 5A-5B illustrate an exemplary design for side-to-side etchant flow in accordance with an embodiment of the present disclosure. FIG. 6 illustrates an exemplary design for the etchant introduction and exit over the entire area of the process substrate in accordance with an embodiment of the present disclosure.

Referring to FIG. 5A, FIG. 5A illustrates a process chamber 501 filled with etchant, along with an inlet manifold 502 and an outlet manifold 503. Additionally, FIG. 5A illustrates the process wafer 504.

Referring to FIG. 5B, FIG. 5B illustrates a cross section of inlet manifold 502 and outlet manifold 503.

Referring to FIG. 6, FIG. 6 illustrates a multilayer frontside cover 601, process wafer 602, etch products 603 as well as the etchant inlet 604 and etchant outlet 605. Furthermore, the local etchant flow direction is identified by element 606.

As shown in FIG. 5A, fluid is introduced and exited from the sides (see 502, 503) of chamber 501. In FIG. 6, fluid is introduced and exited using inlet and outlet ports (see 604, 605) placed over the entire extent of the chamber walls. Manufacturing of these designs is possible using standard Computer Numerical Control (CNC) machines. In one embodiment, multilayer frontside cover 601 is manufactured by bonding of multiple 2D machined pieces, for instance, using polymer welding of machined polytetrafluoroethylene (PTFE) pieces.

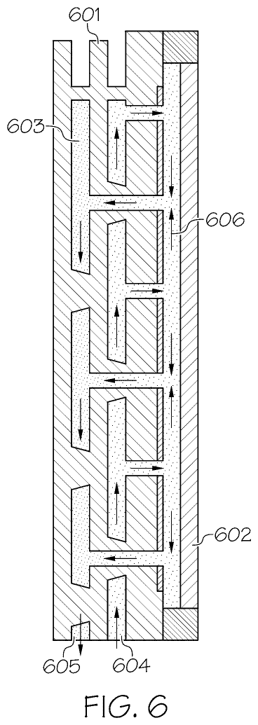

In one embodiment, a spin-spray-type system is used for frontside etchant delivery and circulation. In one embodiment of the system, a rotating arm is used to dispense the new etchant onto the process substrate, where the process substrate is kept stationary. To remove used etchant from the substrate surface, an active strategy could be used, where a second arm, integrated with the first arm or otherwise, could be used to centrifugally move used etchant out. Alternatively, a passive strategy could be used, where the substrate is kept in a vertical orientation, and the force of gravity is used to draw the used etchant down into a collection chamber. The axes of rotation of the arms could either be fixed or movable, coaxial with the process substrate or eccentric. In a second embodiment, the etchant dispense arm is fixed, while the process substrate itself is rotated. In all embodiments of spin-spray-type systems, an AE2 compatible chamber would enclose the entire frontside of the process substrate and be used to contain any etchant that is thrown in various directions by the rotating process substrate and/or etchant dispense arms. An illustration of one of the embodiments described above is shown in FIGS. 7A-7B.

FIGS. 7A-7B illustrate an exemplary spin-spray-type etchant flow system with an eccentrically rotating etchant spray arm and passive gravity-driven etchant outflow in accordance with an embodiment of the present disclosure. In particular, FIG. 7A illustrates the cross-section of the side view of the spin-spray-type etchant flow system and FIG. 7B illustrates a top view of the spin-spray-type etchant flow system.

Referring to FIG. 7A, such a system includes a frontside cover 701, an eccentrically rotating etchant spray arm 702, an etchant inlet 703 and an etchant outlet 704 which is gravity driven. Furthermore, FIG. 7A illustrates etchant 705 and a process wafer 706, which is fixed and vertical.

FIG. 7B also illustrates eccentrically rotating etchant spray arm 703 and process wafer 706 as well as illustrates the direction of rotation (see 707) of spray arm 702.

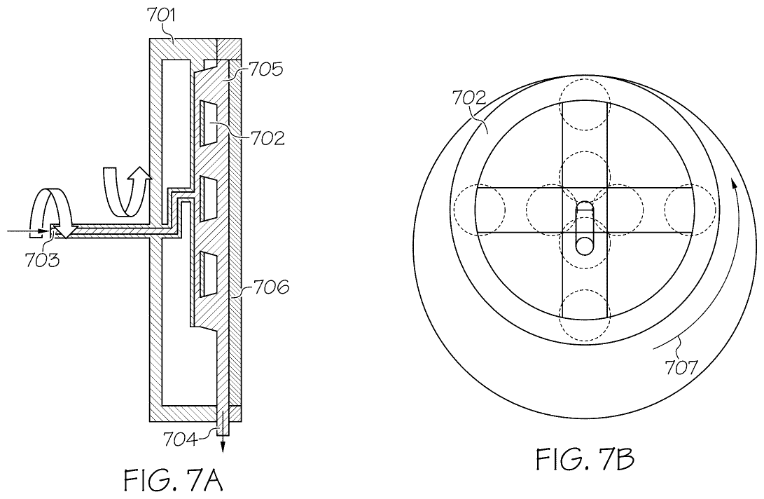

In one embodiment, a system with a sliding etch zone is used. In one embodiment, a group of inlet and outlet nozzles, placed in close proximity to each other, is used to create a locally circulating etchant zone. In one embodiment, the group of nozzles is scanned across the substrate to etch the entire substrate as shown in FIG. 8.

FIG. 8 illustrates an exemplary design with a sliding etch zone in accordance with an embodiment of the present disclosure.

As shown in FIG. 8, process wafer 801 is fixed and horizontal. Furthermore, the design of FIG. 8 includes a sliding etch zone 802 along with an etchant 803, an etchant inlet 804 and an etchant outlet 805. Furthermore, FIG. 8 illustrates a frontside cover 806 and a scannable group 807 of inlets and outlets.

In one embodiment, geometrical elements, such as baffles and fins, are placed inside the etchant chamber to ensure a desired fluid flow. In one embodiment, these are integrally fabricated with the frontside chamber. In one embodiment, Computational Fluid Dynamics (CFD) based fluidic simulations along with design optimization techniques are used to design these geometrical elements.

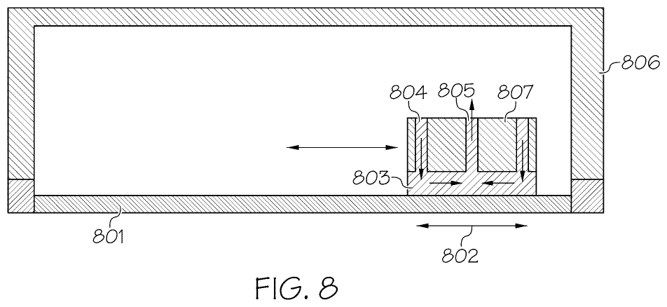

In one embodiment, with respect to active etchant agitation, in-chamber moving assemblies are used to agitate the etchant and prevent stagnation zones. In one embodiment, these assemblies are in the form of a group of crossed arms. In another embodiment, these assemblies are a group of arms with distinct centers-of-rotation. In another embodiment, the moving assemblies are etchant inlet and outlet ports. In another embodiment, the moving assemblies have geometrical elements, such as baffles and fins. In one embodiment, the actuation mechanism for these assemblies are indirect (such as actuation of assemblies with integral magnets using a rotating external magnetic field), or direct (such as using a direct drive motor), or using fluidic reaction and impulsive forces (in a manner similar to reaction and impulse turbine). An exemplary double-axis, double-arm assembly with fluidic actuation is shown in FIGS. 9A-9B.

FIGS. 9A and 9B illustrate an exemplary double-axis, double-arm assembly for etchant agitation in accordance with an embodiment of the present disclosure. In particular, FIG. 9A illustrates the cross-section of the side view of the assembly, whereas, FIG. 9B illustrates a top view of the assembly.

As shown in FIG. 9A, such an assembly includes a frontside cover 901, a process wafer 902, counter rotating etchant agitation arms 903, etchant 904 and an etchant outlet 905.

Referring to FIG. 9B, FIG. 9B illustrates the top view of the assembly which includes process wafer 902 and etchant inlet jets 906.

In one embodiment, the etchant (e.g., etchant 904) being circulated in the etch chamber is mixed and stored in a mixing chamber. In one embodiment, the mixing chamber is placed at a distance from the etch chamber and connected to the etch chamber using AE2-compatible tubing. In one embodiment, the mixing chamber has various monitors of the etchant state, such as concentration monitors, flow monitors, temperature monitors, impurity/precipitant/particle monitors, pressure monitors, etc. In one embodiment, the mixing chamber has various actuation mechanisms to change the etchant state, such as etchant inlets (e.g., etchant inlet jets 906) for etchant precursors to dynamically modify etchant concentration, and heating assemblies to modify the etchant temperature. The flow of the etchant between the mixing chamber and the process chamber, and between the mixing chamber and the precursor storage, could be handled using AE2-compatible pumps.

In one embodiment, etchant precursors are stored in containers, such as the mixing chamber, where the precursor storage containers have precursor state monitors, such as concentration monitors, temperature monitors, impurity/precipitant monitors, pressure monitors, etc., as well as precursor state actuation mechanisms, such as inlets to dynamically modify precursor concentration, and heating assemblies to modify the precursor temperature.

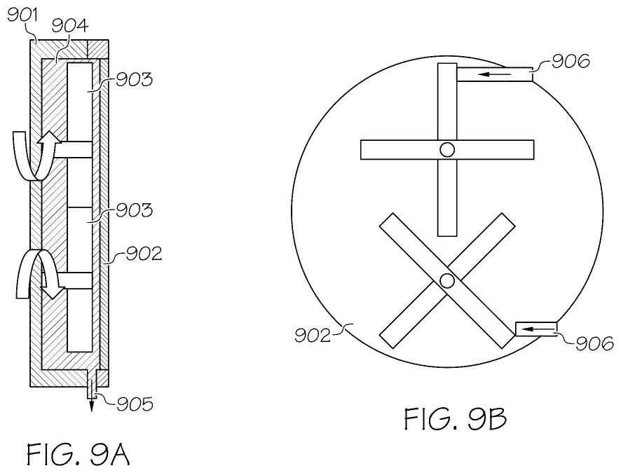

FIG. 10 illustrates an entire etchant flow assembly 1000, with the process chamber, mixing chamber, precursor storage, pump assemblies, and etchant and precursor state sensing and actuation mechanisms, in accordance with an embodiment of the present disclosure.

As shown in FIG. 10, assembly 1000 includes a process wafer 1001, a frontside cover 1002, an etchant inlet 1003 and an etchant outlet 1004. Furthermore, assembly 1000 includes a mixing chamber 1005 with a catalyst influenced chemical etching (CICE)-compatible etchant pump 1006, etchant state sensors 1007 and thermal actuation of the mixing chamber etchant (see element 1008). Additionally, assembly 1000 includes precursor storage units 1009A-1009N, where N is a positive integer number, along with precursor state sensors 1010.

With respect to degassing, one or more of the products of the AE2 process could be in gaseous form. Aggressive production of gases during AE2 can lead to bubble formation in the etchant in the vicinity of the reaction site, which can introduce non-uniformity in the etchant concentration, diminish visibility through the etchant for in-situ metrology for instance, and potentially clog or reduce the efficiency of the etchant flow systems. It is noted that the bubbles do not need to be eliminated altogether but need to be controlled to an extent that they do not hinder in-situ metrology, etchant flow and reaction uniformity. Several methods may be used to reduce bubble formation in the AE2 process as discussed below.

In one embodiment, certain AE2 regimes lead to higher bubble production. Thus, operating in regimes that lead to lesser evolution of gases can reduce the bubble problem.

In one embodiment, a lower etch rate can reduce the rate of bubble production as well. In one embodiment, the lower etch rate is achieved, for instance, by lowering the etchant concentration, or the concentration of the rate-limiting etchant precursors. It can also be achieved by lowering the temperature of the etchant.

In one embodiment, increasing the etchant pressure increases the solubility of gasses in the etchant and thus reduces bubble formation.

In one embodiment, decreasing the temperature of the etchant increases the solubility of gasses in the etchant and could thus be used to reduce bubble formation.

In one embodiment, membrane degasification—PTFE-based AE2-compatible gas-liquid separation membranes, on the process chamber walls, or elsewhere in the etchant path, could be used to selectively extract gasses from the etchant and reduce bubble formation.

In one embodiment, sonication is used to detach bubbles attached to the process substrate surface and drive them into the bulk etchant. The sonication could be achieved using, for instance, piezoelectric elements that are integrated in the front and/or back covers.

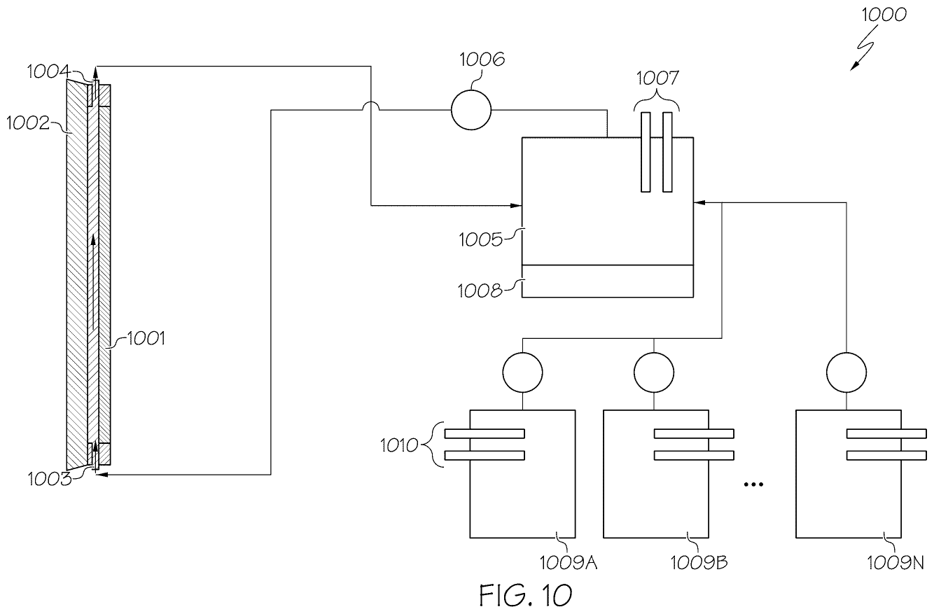

In one embodiment, a vacuum-based degassing chamber is used as part of the mixing chamber, or separately, to reduce the amount of dissolved gasses in the etchant solution. Such a strategy is discussed below in connection with FIG. 11.

In one embodiment, the tool is operated such that the process substrate is vertical during the AE2 process, so that bubbles travel up against gravity to the top of the tool instead of travelling to the front of the tool in a horizontal configuration and obstructing the view for potential in-situ metrology.

In one embodiment, bubbles stuck to the surface of the process substrate are released using a movable arm with a knife edge that moves across the surface of the process substrate while maintaining a small gap between the substrate and the knife edge (millimeter-scale or lower).

Referring now to FIG. 11, FIG. 11 illustrates the vacuum-based degassing strategy in accordance with an embodiment of the present disclosure.

As shown in FIG. 11, H₂ bubbles 1101 in an etch solution of process wafer 1102 travel via etchant outlet 1103 and into degassing chamber 1104 followed by being inputted to the etchant solution via etchant inlet 1105. Furthermore, as illustrated in FIG. 11, there is a vacuum or partial vacuum for H₂ (see element 1106). Additionally, FIG. 11 illustrates the frontside cover 1107.

In one embodiment, with respect to reaction quenching and reaction starting, for a uniform etch across the whole substrate, the spatial variation in the start and stop of the AE2 process needs to be carefully managed. For instance, for a wet process, if the reaction quenching fluid (water, for instance) is injected at one end of the process substrate and it takes 5 seconds for the quenching front to cover the entire substrate at a sample etch rate of 1 μm/min, this would result in an etch height variation of ˜80 nm across the entire substrate. Similarly, if the etchant at the start of the AE2 process is injected at one end of the process substrate and it takes 5 seconds for the etchant front to cover the entire substrate at a sample etch rate of 1 μm/min, this would result in an etch height variation of ˜80 nm across the entire substrate. Several methods could be used to reduce the etch height variation during reaction quenching and starting.

With respect to etch rate reduction, reducing the etch rate, prior to reaction quenching or over the entire etch, can reduce the etch height variation. In one embodiment, the etch rate reduction is achieved by changing the relative concentrations of the etchant precursors (in the mixing chamber), or by reducing the temperature of the substrate (which would lead to a corresponding drop in the etch rate).

In one embodiment, with respect to etchant and quenching fluid injection from the front of the substrate, the flow path of the etchant is reduced by introducing the etchant and the quenching fluids from the front of the substrate. This would reduce the time stray etchant remains in the process chamber, thus reducing the reaction quenching time and the corresponding etch non-uniformity. Similarly, it would reduce the amount of time it takes for etchant to be introduced during etch initiation. Many of the methods described above in connection with the etch circulation could be used for frontside introduction of etchants and the quenching fluid. For instance, the design shown in FIG. 6 could be utilized.

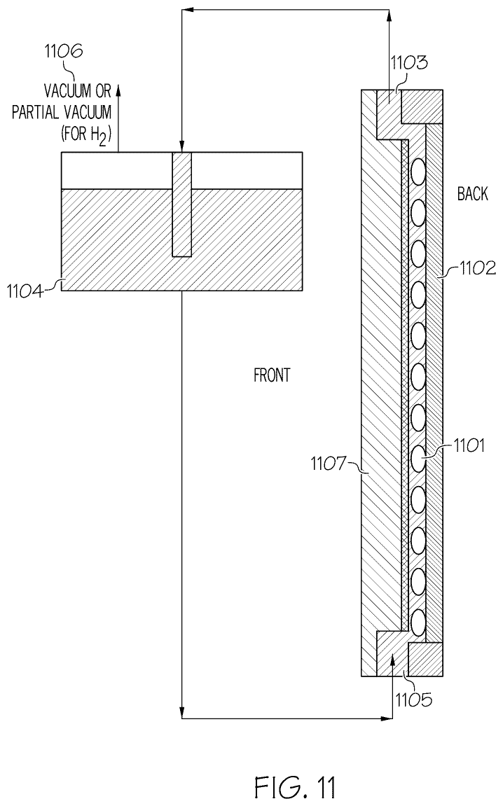

With respect to etchant freezing, the process substrate could be cooled, using peltier elements, for instance, such that a thin layer of etchant right next to the substrate freezes (which would also stop the AE2 reaction). The bulk unfrozen etchant could then be replaced with a reaction quenching fluid, such as water, while the etchant right next to the substrate is still frozen. In one embodiment, the thin layer of frozen etchant is then heated so that it melts and rapidly dissipates into the bulk quenching fluid which is present right next to it. An illustration of such a process is shown in FIGS. 12A-12D.

FIGS. 12A-12D illustrate exemplary etchant freezing-based reaction quenching in accordance with an embodiment of the present disclosure.

In particular, FIG. 12A illustrates a wafer chuck 1201, a process wafer 1202, a thermoelectric cooler (TEC) 1203 at sub-freezing temperature, a frontside cover 1204, an etchant inlet 1205, an etchant outlet 1206 and a seal 1207.

As shown in FIG. 12B, FIG. 12B illustrates a thin layer of frozen etchant (see element 1208). FIG. 12C illustrates replacing the bulk etchant solution with quenching liquid (see element 1209). FIG. 12D illustrates a thin layer of etchant melting off (see element 1210) and the TEC set to heat (see element 1211).

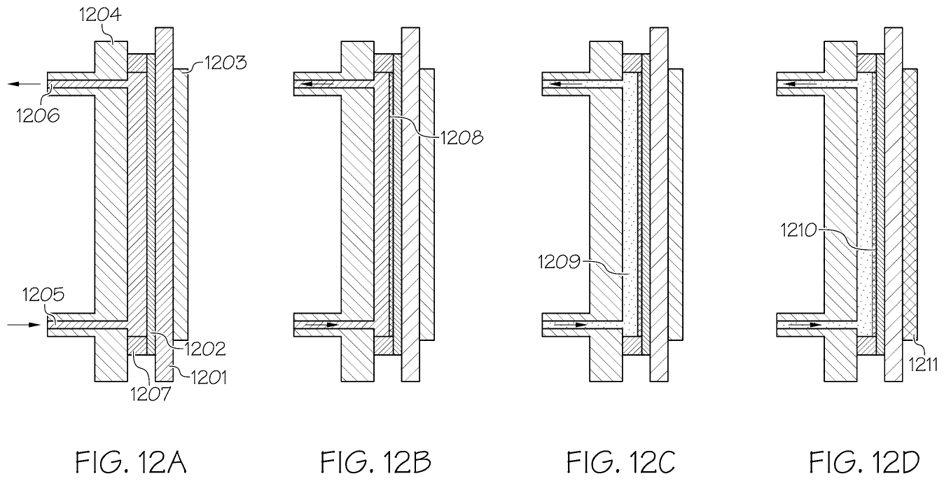

Alternatively, after the freezing process, the bulk fluid is replaced with air, which is subsequently evacuated such that the thin frozen layer of etchant sublimates. In one embodiment, the evacuation is achieved by placing the entire etch chamber in a larger AE2-compatible vacuum chamber, or alternatively, connecting a AE2-compatible vacuum pump, such as a bellow pump, to the reaction chamber itself and drawing out the filled air. An illustration of such an embodiment is shown in FIGS. 13A-13D.

FIGS. 13A-13D illustrate etchant freezing and sublimation-based reaction quenching in accordance with an embodiment of the present disclosure.

As shown in FIG. 13A, FIG. 13A illustrates a wafer chuck 1301, a process wafer 1302, a thermoelectric cooler (TEC) 1303 at sub-freezing temperature, a frontside cover 1304, an etchant inlet 1305, an etchant outlet 1306 and a seal 1307. Furthermore, FIG. 13A illustrates a large vacuum chamber 1308.

FIG. 13B illustrates a thin layer of frozen etchant 1309. FIG. 13C illustrates the replacement of the bulk etchant solution with air (see element 1310). FIG. 13D illustrates a thin layer of etchant sublimating off (see element 1311) and the TEC set to heat (see element 1312). Furthermore, FIG. 13D illustrates the vacuum turned on (see element 1313).

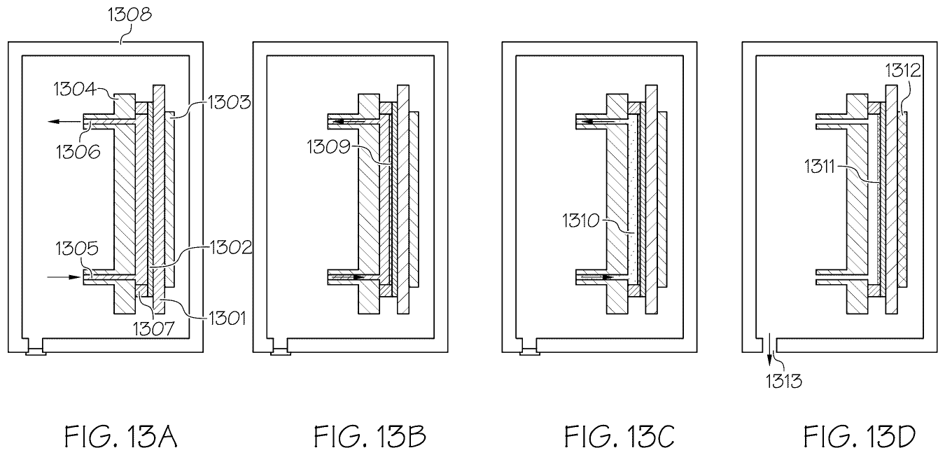

With respect to thermal compensation, an array of thermal actuators could be used to actively compensate for any etch rate variation that is caused during etch initiation and quenching. Several methods may be used to achieve the thermal actuation. An exemplary design for thermal compensation is provided in FIG. 14.

FIG. 14 illustrates an exemplary design for thermal compensation during reaction quenching and starting in accordance with an embodiment of the present disclosure.

As shown in FIG. 14, FIG. 14 illustrates a wafer chuck 1401, a process wafer 1402, a frontside cover 1403, an etchant inlet 1404 and an etchant outlet 1405. Furthermore, as shown in FIG. 14, FIG. 14 illustrates a grid of independently controllable thermoelectric coolers 1406.

With respect to etchant evaporation in a vacuum, the entire etchant in the reaction chamber, for instance when a thin sheet of reactant is used, could be rapidly evaporated using vacuum. The evacuation could be achieved by placing the entire etch chamber in a larger AE2-compatible vacuum chamber, or alternatively, connecting a AE2-compatible vacuum pump, such as a bellow pump, to the reaction chamber itself and drawing out the filled air.

In one embodiment, with respect to process variation control, spatial variation in the concentration of the etchant and etch products, local etchant flow rate, etchant temperature, pattern density variation, and substrate edge effects can lead to variation in the quality of the etch (degree of porosity, wall surface roughness, wall angle) as well as variation in the etch rate. In one embodiment, a feedback-based system is used to control process variation. In another embodiment, a purely feedforward approach is used, where the likely process variation is known ahead of time, and local actuation methods (such as thermal actuation) are used in an open-loop manner to correct the known process variation. In another embodiment, a hybrid approach is used where known process variation trends are combined with real-time process variation measurements for controlling the process actuators.

With respect to metrology, a crucial aspect of the AE2 process is etch depth uniformity and control. The etch depth as well as any porous layers that are formed during AE2 can be measured and characterized using many destructive and non-destructive methods, such as Scanning Electron Microscopy (SEM), Transmission Electron Microscopy (TEM), Atomic Force Microscopy (AFM), Optical Scatterometry, Ellipsometry, small angle X-ray scatterometry, through focus Scanning Optical Microscopy (TSOM), Helium Ion microscopy, proton microscopy, etc.

For in-situ measurements of the etch profiles, in one embodiment, the AE2 tool design ensures that the front of the substrate as well as the back can be imaged using one or more wavelengths of light. In one embodiment, the design of the AE2 tool accounts for the transmission of light through the components and electrolyte onto the back of the wafer for creating an ohmic contact, and onto the front of the wafer for optical metrology. In one embodiment, this can be accomplished by using sapphire windows on each side of the process chamber or using optic fiber cables. The sapphire windows and/or optic fiber components may be coated with etchant resistant materials, such as Teflon or aluminum oxide, while maintaining the transparency of the substrate. In one embodiment, the electrodes are made of platinum wires, platinum meshes, indium tin oxide with etchant resistant coating, doped silicon wafers with optional coating of etchant resistant material, such as carbon, diamond, aluminum oxide, Cr, etc. In one embodiment, the etchant resistant material can further be doped to improve conductivity. In one embodiment, the geometry of the electrode is optimized to ensure uniform electric fields while also ensuring light passes through, such as with an annular ring. Mirrors, such as chrome-coated silicon or thin chrome plates, may also be used to direct light onto the top of the substrate. In one embodiment, one or more electrodes are used on each side of the wafer in the process chamber.

In one embodiment, optical metrology is used in-situ to examine the substrate during the etch process since the optical properties of silicon nanostructures lead to a wide spectrum of colors and changes in hue.

In one embodiment, an optical imaging system will be used to measure the reflectance over large sample areas in real-time. The samples will be illuminated with light with known spectral content. The light can be white light, colored light, single wavelength, in a narrow or wide spectral band, etc. A camera can then image the samples reflecting this light. The camera may be monochrome, color (RGB), multi-spectral, hyperspectral, etc. Multi-megapixel resolutions found in modern cameras make it possible to observe millions of points on a sample simultaneously. Video framerates enable in-situ real-time measurement. Each image can be divided by an image of a reference to calculate reflectance images of the samples or used as they are. An image processing algorithm will determine process completion and gather data about uniformity of CICE both within samples and sample to sample.

Visible wavelengths of light from the backside of the wafer cannot detect the etch depth during AE2. Infrared (IR) spectroscopy can be used instead, as is it a rapid, non-destructive and an in-situ method of etch state detection. The images acquired using IR metrology from the back of the wafer, along with the visible light images acquired from the front of the wafer during the etch, can be used to create a 3D image of the etch front and the substrate before, during, and after the etch. This can be used to detect process excursions and progress of the etch in situ. In one embodiment, the snapshots are acquired at regular time intervals, where the time interval can be smaller than a minute and as small as 1 ms. These snapshots when taken at higher than 100 kHz can be used for real-time process control, where the feedback is used to adjust or refine one of the following control variables locally and/or globally: electric fields, temperature, etchant concentration, magnetic field, illumination, vapor pressure, etc. Such snapshots can also be used at the end of etching of the wafer to reconstruct the 3D geometry of the final etched substrate which could include non-porous, porous, and multiple materials (SiGe), etc. Such information can be used for quality control or for automated process control where the feedback is done on a wafer-to-wafer basis.

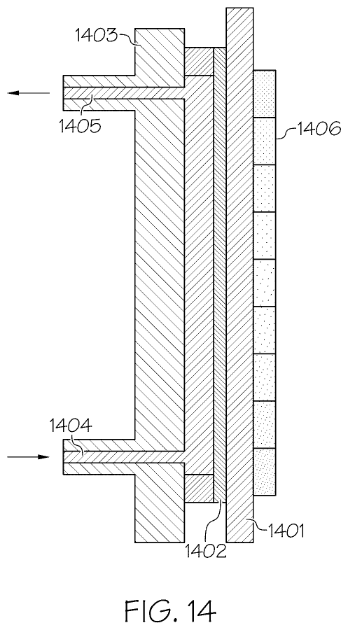

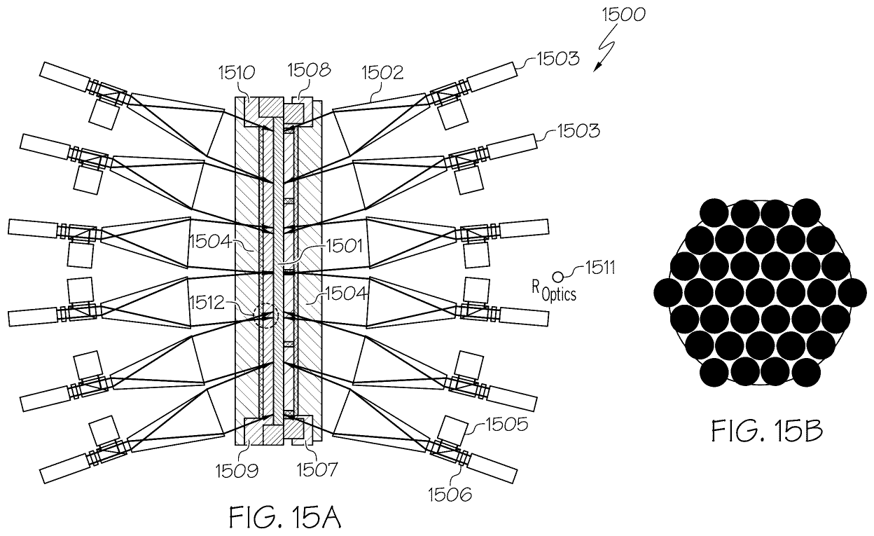

In one embodiment, the spatial variation in etch rate, or a proxy thereof (such as the unique spectral signature corresponding to a given etch feature height), could be monitored in-situ. This could, for instance, be achieved using in-situ spectrophotometry of the process substrate. The metrology could either be reflective or transmissive. In one embodiment, IR wavelengths are used in case transmissive metrology is required. The metrology could either be performed in real-time (synchronously) or asynchronously with the AE2 process. Depending on whether the metrology is reflective or transmissive, the frontside and/or the backside covers may be fabricated using AE2-compatible transparent materials. Crystalline sapphire is one such material, and this is available in substrate form. In one embodiment, the thickness of the etchant sheet is maintained such that a large portion of the incident irradiance passes through the etchant (for instance, 90% transmittance, 80%, 70%, 60%, etc.). FIGS. 15A-15B and 16 illustrate two exemplary systems.

FIGS. 15A-15B illustrate an exemplary in-situ metrology system 1500 with total substrate coverage in accordance with an embodiment of the present disclosure. Since both the frontside and backside of the process substrate 1501 are covered, metrology is available in both transmissive and reflective modes.

Referring to FIG. 15A, FIG. 15A illustrates the front and back of the in-situ metrology system 1500, which includes focusing optics 1502, imagers 1503, sapphire frontside and backside covers 1504, a light source 1505, optical filters 1506, a backside fluid inlet 1507, a backside fluid outlet 1508, an etchant inlet 1509 and an etchant outlet 1510. Furthermore, FIG. 15A illustrates a finite radius of curvature R_{optics} 1511 and overlapping fields-of-view enable gap-free metrology and actuation (see element 1512).

FIG. 15B illustrates a top view showing coverage of metrology system 1500.

FIG. 16 illustrates an exemplary in-situ metrology system 1600 with scannable optics in accordance with an embodiment of the present disclosure.

As shown in FIG. 16, in-situ metrology system 1600 includes an imager assembly 1601 on the XY stage as well as illustrates a process wafer 1602.

In one embodiment, the spatial variation in the AE2 etch, or a proxy thereof (such as the unique spectral signature corresponding to a given etch feature height), could be measured ex-situ. The metrology could either be reflective or transmissive. In one embodiment, IR wavelengths are used in case transmissive metrology is required. In one embodiment, the ex-situ metrology chamber is placed in close proximity to the etch chamber to enable quick transfer of a processed substrate. In one embodiment, the metrology system itself is not made of AE2 compatible materials but is enclosed in a larger AE2 compatible chamber.

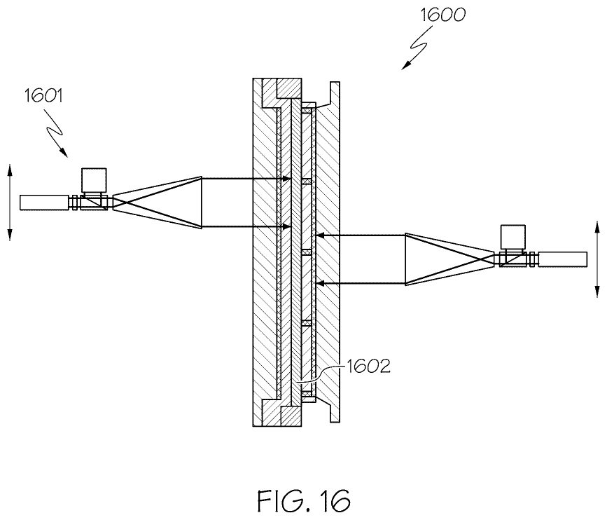

In one embodiment, with respect to thermal actuation, controlled variation in local temperature is used to produce corresponding variations in the process substrate etch rate. In one embodiment, the thermal actuation of the etch rate is used to actively control spatial variations in the etch rate. In one embodiment, thermal actuation is achieved using contact-based solutions, such as thermoelectric cooling, or using non-contact solutions, such as heating using DMD-modulated light at visible or IR wavelengths. In one embodiment, the thermal actuators are distributed over the entire extent of the process substrate or cover a portion of the process substrate and could optionally be scanned across the process substrate. In one embodiment, thermal actuation is implemented from the frontside of the process substrate, the backside, or from both sides. FIGS. 14 and 17 illustrate two such exemplary systems.

FIG. 17 illustrates an exemplary system for Digital Micromirror Device (DMD)-modulated substrate thermal control in accordance with an embodiment of the present disclosure.

As shown in FIG. 17, FIG. 17 illustrates focusing optics 1502, imagers 1503, sapphire frontside and backside covers 1504, optical filters 1506, a backside fluid inlet 1507, a backside fluid outlet 1508, an etchant inlet 1509 and an etchant outlet 1510. Furthermore, FIG. 17 illustrates a light source plus a DMD assembly 1701 along with the backside fluid 1702, which can be used to set the wafer global temperature.

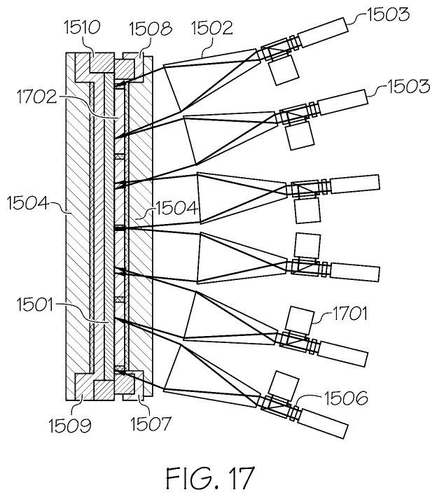

In one embodiment, electric fields are used to control nanopore dimensions during the AE2 process. In one embodiment, an array of electrodes patterned on the front and back covers are used to produce local electric fields to control the local pore parameters in the process substrates. AE2-compatible electrode materials are available. An exemplary system for electric filed control is shown in FIG. 18.

FIG. 18 illustrates the cross-section of the AE2 tool for electric field control in accordance with an embodiment of the present disclosure.

As shown in FIG. 18, FIG. 18 illustrates the process wafer 1801, the frontside transparent electrode 1802, the backside transparent electrode 1803 and backside illumination 1804.

In one embodiment, pattern density variations are adjusted. In one embodiment, pattern density variations, and their potential effects on etch rate and quality, are addressed using a variety of the methods described above. In one embodiment, a denser array of process actuators are used in regions of higher pattern density. In another embodiment, sliding etch zones, with the ability to locally change the etchant concentration, are used to account for variation in pattern density.

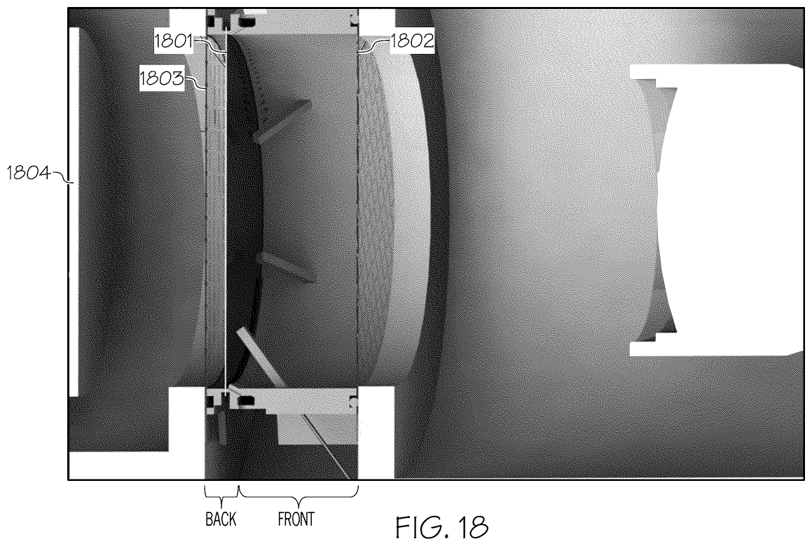

In one embodiment, with respect to substrate edge effects, abrupt changes in the fluid meniscus, etchant concentration, electric fields, etc. near the process substrate edges could lead to a large variation in etch characteristics near the edges. In one embodiment, such a variation in etch characteristics is addressed by careful design of the substrate edge exclusion zone, such that a large portion of the etch variation is present outside the exclusion zone. In one embodiment, front cover seals are contacted on the outside of the substrate periphery as shown in FIGS. 19A-19B. In another embodiment, a spin-spray type system is used with no peripheral seals on the substrate frontside.

FIGS. 19A-19B illustrate an exemplary edge contact design showing frontside seals that make contact on the outside edge of the process substrate in accordance with an embodiment of the present disclosure.

Referring to FIG. 19A, FIG. 19A illustrates a wafer chuck 1901, a process wafer 1902 and a frontside cover 1903. FIG. 19B illustrates an expanded view of the device region on the process wafer (see element 1904). FIG. 19B further illustrates an edge exclusion zone 1905, the frontside seal contacts 1906 on the outer edge of process wafer 1902, and the region 1907 of high variation in the etch. As illustrated in FIG. 19B, edge exclusion zone 1905 is larger in comparison to the region of high etch variation 1907 associated with the substrate edge.

In one embodiment, the backside contact is established using chucks made of AE2-compatible materials, such as fluoropolymer or sapphire. In one embodiment, the chuck has a pin-type contact with the substrate backside, ring type contact, or a flat areal contact. In one embodiment, the substrate is held against the backside chuck using clamps that attach to the substrate edge, using vacuum, or using electrostatics. In one embodiment, the space between the process substrate and the backside chuck (if present), is filed with a fluid, which could be the etchant or a generic electrolyte. In one embodiment, the backside fluid is used to facilitate electric field control during the AE2 process. The backside fluid could either be stationary or circulating. In one embodiment, frontside etchant flow strategies (described above) are used for backside fluid flow as well. Fugues 20 and 21 show exemplary designs for backside contact.

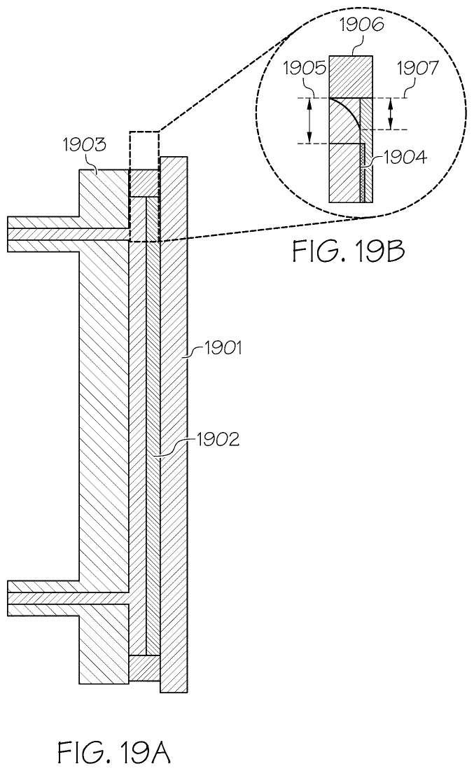

FIG. 20 illustrates an exemplary backside contact with backside fluid in accordance with an embodiment of the present disclosure.

As shown in FIG. 20, FIG. 20 illustrates a process wafer 2001, a wafer chuck (pin-type) 2002, chuck pins 2003 and backside contact fluid 2004. In one embodiment, backside contact fluid 2004 is used to enable electric field control and global temperature control for the process substrate.

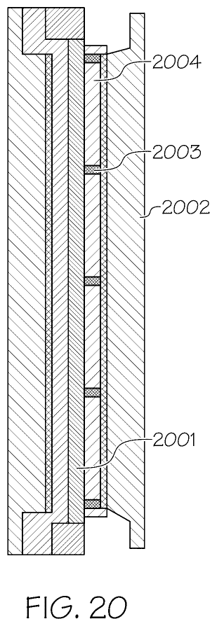

FIG. 21 illustrates an exemplary backside contact using a vacuum chuck 2101 in accordance with an embodiment of the present disclosure.

In one embodiment, electric fields are used to modulate the nanopore dimensions during the AE2 process. In one embodiment, the substrate contains a valve metal. In one embodiment, the substrate is part of an anode in an electrochemical cell. In one embodiment, the substrate is connected to an anode using conductive clamps, conductive fluid, conductive wires, and/or conductive pins.

In one embodiment, electrodes patterned on the front and back covers are used to produce electric fields to control the pore parameters in the process substrate. It is noted that patterning of the AE2-compatible thin electrode layer on flat substrates is available. It is further noted that to create an ohmic contact for establishing a current through the process substrate, backside illumination can be used. An exemplary system for electric field control is shown in FIG. 18.

In one embodiment, the electrolytes on either side of the substrate are not the same as the etchant. On the front side of the substrate, the electrolyte is same as the AE2 etchant. The electrolyte on the back of the substrate may include a chemical that provides a high-conductivity path between the substrate and an electrode. In one embodiment, the electrode is an anode.

In one embodiment, the seals between the frontside process chamber, the process substrate, and the backside substrate cover are AE2-compatible. In one embodiment, the seals are also CMOS-compatible. In one embodiment, the seal is also integrally fabricated in the front and backside process covers. To seal rotating assemblies, rotary seals (integrally fabricated or otherwise) may be used.

In one embodiment, intermittent cleaning of the process chamber with a metal contaminant cleaning solution, such as nitric acid, is used to remove metal impurities that might accumulate on the process chamber. In one embodiment, the tool maintenance schedule is divided up into high frequency intermittent metal cleans, and lower frequency maintenance involving full tool disassembly and clean.

It is noted that the phase of the etchant could be either vapor or liquid. For vapor-phase AE2, electric field creation and control are achieved using atmospheric pressure plasmas.

In one embodiment, the AE2 tool consists of a spin-spray type system for frontside etchant delivery, a vacuum chuck on the backside, global (single setpoint) temperature control of the frontside etchant, local contact or contactless temperature control on the substrate backside, flow or freezing-based reaction quenching, ex-situ reflective scatterometry, and optional in-situ IR-based transmissive scatterometry

In another embodiment, the AE2 tool consists of a thick fluid sheet for a frontside etchant, a thick fluid sheet on the backside, global (single setpoint) temperature control of the frontside etchant, global (single setpoint) temperature control on the substrate backside, flow-based reaction quenching, ex-situ reflective scatterometry, and diamond-like coating (DLC) based electric field creation. A “thick fluid sheet,” as used herein, refers to a fluid sheet with a thickness in which the fluid sheet has a light transmission (at the relevant metrology spectrum) of 50% or lower.

In another embodiment, the AE2 tool consists of a thick fluid sheet for the frontside etchant, a thin fluid sheet on the backside, global (single setpoint) temperature control of the frontside etchant, global (single setpoint) or local temperature control on the substrate backside, flow-based reaction quenching, ex-situ reflective scatterometry, optional in-situ IR-based transmissive scatterometry, and diamond-like coating (DLC) based electric field creation. A “thin fluid sheet,” as used herein, refers to a fluid sheet with a thickness in which the fluid sheet has a light transmission (at the relevant metrology spectrum) of 50% or higher.

In another embodiment, the AE2 tool consists of a thick fluid sheet for the frontside etchant, a vacuum chuck on the backside, global (single setpoint) temperature control of the frontside etchant, global (single setpoint) or local temperature control on the substrate backside, flow-based reaction quenching, ex-situ reflective scatterometry, and optional in-situ IR-based transmissive scatterometry.

In another embodiment, the AE2 tool consists of a thin fluid sheet for the frontside etchant, a thick fluid sheet on the backside, global (single setpoint) or local temperature control on the frontside, global (single setpoint) temperature control on the substrate backside, flow-based reaction quenching, in-situ reflective scatterometry, and optional ex-situ reflective scatterometry, and diamond-like carbon (DLC)-based electric field creation.

In another embodiment, the AE2 tool consists of a thin fluid sheet for the frontside etchant, a thin fluid sheet on the backside, global (single setpoint) or local temperature control on the frontside, global (single setpoint) or local temperature control on the substrate backside, flow-based reaction quenching, in-situ reflective scatterometry, optional in-situ IR-based transmissive scatterometry, optional ex-situ reflective scatterometry, and DLC-based electric field creation.

In another embodiment, the AE2 tool consists of a thin fluid sheet for the frontside etchant, a vacuum chuck on the backside, global (single setpoint) or local temperature control on the frontside, global (single setpoint) or local temperature control on the substrate backside, flow or freezing-based reaction quenching, in-situ reflective scatterometry, optional in-situ IR-based transmissive scatterometry, optional ex-situ reflective scatterometry, and DLC-based electric field creation.

In another embodiment, the AE2 tool consists of a vapor etchant on the frontside, a thick fluid sheet on the backside, global (single setpoint) or local temperature control on the frontside, global (single setpoint) temperature control on the substrate backside, in-situ reflective scatterometry, optional ex-situ reflective scatterometry, optional plasma and DLC-based electric field creation.

In another embodiment, the AE2 tool consists of a vapor etchant on the frontside, a thin fluid sheet on the backside, global (single setpoint) or local temperature control on the frontside, global (single setpoint) or local temperature control on the substrate backside, in-situ reflective scatterometry, optional in-situ IR-based transmissive scatterometry, optional ex-situ reflective scatterometry, optional plasma and DLC-based electric field creation.

In another embodiment, the AE2 tool consists of a vapor etchant on the frontside, a vacuum chuck on the backside, global (single setpoint) or local temperature control on the frontside, global (single setpoint) or local temperature control on the substrate backside, in-situ reflective scatterometry, optional in-situ IR-based transmissive scatterometry, and optional ex-situ reflective scatterometry.

In another embodiment, the AE2 tool consists of a variable thickness fluid sheet for the frontside etchant. In another embodiment, the AE2 tool consists of a variable thickness fluid sheet on the backside. In one embodiment, the variable thickness fluid sheet designs are implemented using deformable frontside and backside cover assemblies, for instance, using deformable polymer bellows and/or diaphragms.

In one embodiment, a tool is used for creating high aspect ratio holes in valve metals, where a valve metal layer with a seed pattern is anodized in the pore formation regime (hard anodization regimes, and/or mild anodization regimes). In one embodiment, hole parameters (which could include hole density, hole diameter, hole depth, hole pitch, wall thickness, etc.) are modulated using one or more actuators. In one embodiment, hole parameters are measured using one or more measurement devices. In one embodiment, the actuators are thermal actuators, electrochemical actuators, flow control devices, and/or concentration control devices. In one embodiment, the measurement devices are spectrometers, and/or spectrophotometers. In one embodiment, the measurement devices are reflectance-based, and/or transmittance-based devices.

The following describes new processes and applications for the previously discussed Atomically precise Electrochemical Etching (AE2) process. In one embodiment, AE2 is used to create arbitrary high aspect ratio nanostructures in a variety of substrates including silicon, aluminum oxide, etc. In one embodiment, the substrate material is one of or a combination of the following: silicon, a silicon containing material, silicon oxide, spin-on oxide, silicon carbide, silicon nitride, polycrystalline silicon, amorphous silicon, aluminum oxide, metal, a polymer, a spin-on polymer, carbon, a carbon containing material, a metalloid, boron, boron carbide, and boron nitride. In one embodiment, the height of such high aspect ratio nanostructures (including multi-layered high aspect ratio nanostructures) is larger than one of the following: 10 μm, 20 μm. 50 μm, 100 μm, 200 μm, and 400 μm. In one embodiment, a feature pitch of such high aspect ratio nanostructures (including multi-layered high aspect ratio nanostructures) is below one of the following: 500 nm, 200 nm, 100 nm, 50 nm, 20 nm, 10 nm, and 5 nm. In one embodiment, a final aspect ratio of the multi-layered high aspect ratio nanostructures is larger than one of the following: 10:1, 20:1, 50:1, 100:1, 200:1, 500:1, 1000:1, 2000:1, 5000:1, 10000:1, 50000:1, and 100000:1.

In one embodiment, AE2 includes methods to create such nanostructures in silicon (and other substrates) using the CICE process (also referred to as MACE, MacEtch, and AToMM). AE2 can also be used to create nanostructures in valve-metal oxides (valve-metals include Al, Mg, Zr, Nb, Sn, Hf, Ta, W, Bi, etc.).

In one embodiment, the etchant chemistries for creating Anodic Valve-metal Oxides (AVOs), of which Anodic Aluminum Oxide (AAO) is a type, include one or more of the following acids: sulphuric, oxalic, selenic, tartaric, malonic, phosphonic, phosphoric, phosphonoacetic, malic and etidronic acids.

The following discusses very-high aspect ratio nanowire fabrication.

In one embodiment, nanowires with extremely high aspect ratios are fabricated. In one embodiment, the nanowires comprise functional materials including boron, boron nitride, boron oxide, lithium, silicon, etc. An example of such high aspect ratio nanowires is provided in Ruhl et al., “A Non-Thermal Laser-Driven Mixed Fuel Nuclear Fusion Reactor Concept,” arXiv:2202.03170, 2022, which is incorporated by reference herein in its entirety. Another example of high aspect ratio nanowires (silicon nanowires in this case) is for solid-state battery applications. In one embodiment, the nanowires are sub-500 nm, sub-200 nm, sub-100 nm, sub-50 nm, sub-30 nm, sub-20 nm, or sub-10 nm in diameter. In one embodiment, the nanowires are sub-2 μm, sub-1 μm, sub-800 μm, sub-500 nm, sub-300 nm, sub-200 nm, or sub-100 nm in pitch. In one embodiment, the nanowires are over 1 μm, over 2 μm, over 5 μm, over 10 μm, over 20 μm, over 30 μm, over 50 μm, over 70 μm, over 100 μm, over 120 μm, over 150 μm, over 200 μm, or over 300 μm in height. In one embodiment, the nanowires also contain auxiliary materials to act as encapsulants for the functional material (for instance, against chemical damage), or to act as charge conductors. Exemplary auxiliary materials include carbon, boron nitride, doped boron nitride, p-doped boron nitride, polysilicon, doped polysilicon, diamond, doped diamond, boron doped diamond, silicon nitride, silicon carbide, silicon dioxide, polymers, fluoropolymers, titanium nitride, etc. In one embodiment, auxiliary materials are optionally treated as being part of functional materials.

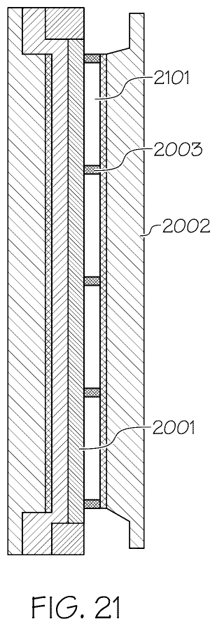

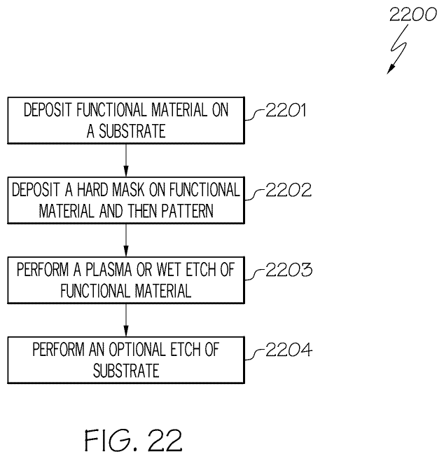

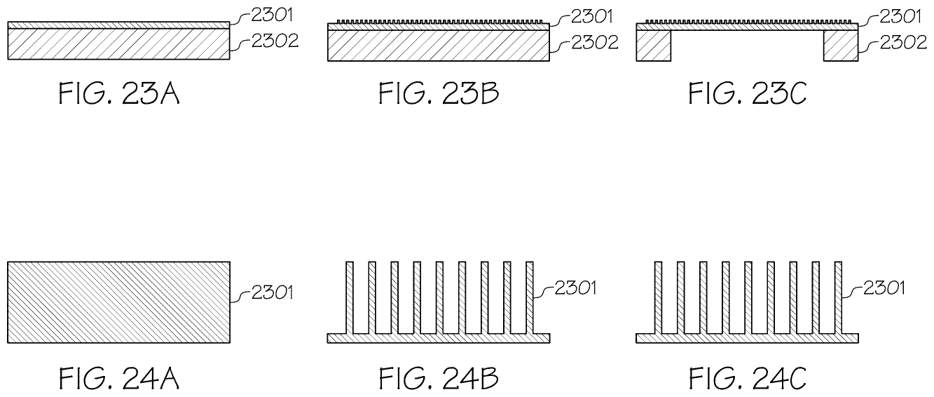

In one embodiment, RIE-based etching of functional material is performed to form nanowires directly as shown in FIGS. 22, 23A-23C and 24A-24C. FIG. 22 is a flowchart of a method 2200 for the formation of nanowires of functional material in accordance with an embodiment of the present disclosure. FIGS. 23A-23C depict the cross-sectional views for the formation of nanowires of functional material using the steps described in FIG. 22 in accordance with an embodiment of the present disclosure. FIGS. 24A-24C depict the cross-sectional views of the functional material during the process of forming nanowires of functional material in accordance with an embodiment of the present disclosure.

Referring to FIG. 22, in conjunction with FIGS. 23A-23C and 24A-24C, in step 2201, functional material 2301 is deposited on a substrate 2302 (e.g., silicon) as shown in FIGS. 23A, 24A. In one embodiment, functional material 2301 is deposited using chemical vapor deposition.

In step 2202, a hard mask is deposited on functional material 2301 and then patterned, such as via nanoimprint lithography (NIL) or any other patterning technique along with a descum etch and pattern transfer to the hard mask.

In step 2203, a plasma or wet etch of functional material 2301 is performed as shown in FIGS. 23B, 24B.

In step 2204, an optional etch (e.g., deep reactive ion etching (DRIE)) of substrate 2302 is performed as shown in FIGS. 23C, 24C.

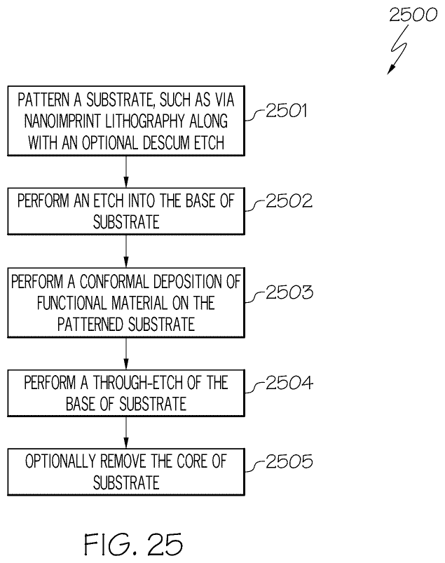

In another embodiment, a core-shell approach is utilized, in which etching (using MACE or plasma etching) of silicon nanowires is performed, and subsequently, the functional material is coated (using CVD, or ALD, for instance), around the silicon core. The central core of silicon could either stay embedded in the final functional material nanowires, or alternatively, the core could be selectively etched and subsequently filled with the same or a different functional material as discussed below in connection with FIGS. 25, 26A-26C and 27A-27C.

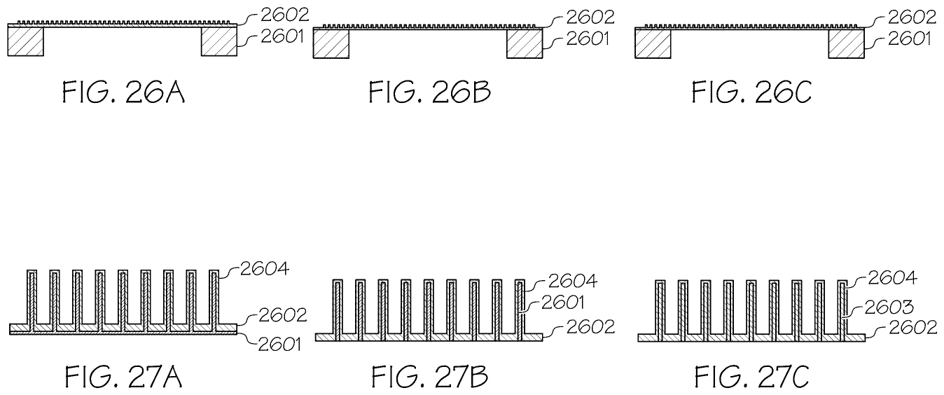

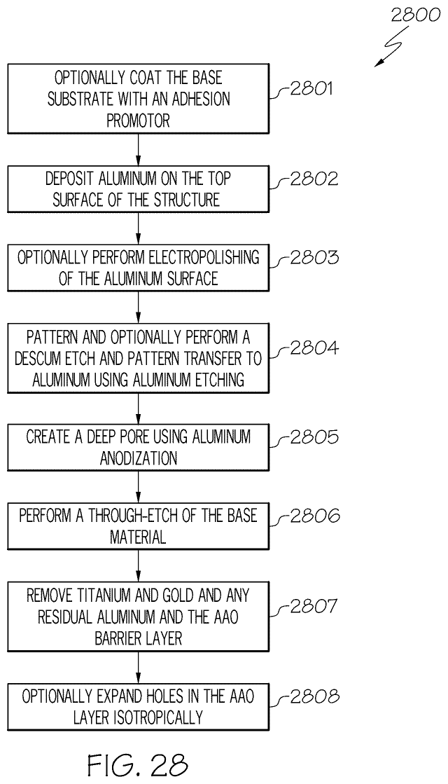

FIG. 25 is a flowchart of a method 2500 for forming nanowires of a functional material (e.g., boron) in accordance with an embodiment of the present disclosure. FIGS. 26A-26C depict the various versions of the final structure that result from utilizing the method of FIG. 25 in accordance with an embodiment of the present disclosure. FIGS. 27A-27C depict the cross-sectional views of the final structures of FIGS. 26A-26C, respectively, in accordance with an embodiment of the present disclosure.

Referring to FIG. 25, in step 2501, a substrate 2601 is patterned, such as via nanoimprint lithography along with an optional descum etch.

In step 2502, an etch is performed into the base of substrate 2601, such as via metal assisted chemical etching (MACE).

In step 2503, a conformal deposition of functional material (functional material 1) 2602 on the patterned substrate 2601 is performed forming nanostructures 2604, such as via chemical vapor deposition.

In step 2504, a through-etch of the base of substrate 2601 is performed, such as via DRIE.

In step 2505, the core of substrate 2601 is optionally removed, such as by using an etch process that etches the base of substrate 2601 selectively over functional material 2602 which for a silicon base material could be a KOH-based, an XeF₂⁻ based, a fluorine-based plasma etch, etc., where the resulting final structure is shown in FIG. 26A.

Referring to FIG. 26A, the final structure includes a thin layer of the base substrate 2601 below functional material 2602, where the through-etch of the base of substrate 2601 is timed to leave behind a thin layer of the base of substrate 2601 below functional material 2602. FIG. 27A depicts a cross-sectional view of the final structure of FIG. 26A.

FIG. 26B illustrates the final structure which includes a nanostructured core of base material of substrate 2601 with an overcoat of functional material 2602. FIG. 27B depicts a cross-sectional view of the final structure of FIG. 26B.

Referring again to step 2505, in one embodiment, after optionally removing the core, functional material (functional material 2) 2603 is deposited, such as via CVD, ALD, etc. as shown in FIGS. 26C and 27C. In one embodiment, the material of functional material (functional material 2) 2603 is the same as the material of functional material (functional material 1) 2602.

In one embodiment, the nanowires 2604 of functional material 2601 as depicted in FIGS. 27A-27C that are formed in the resulting structure are electrostatic-based nanowires.

In one embodiment, the functional material nanowires 2604 are formed in an iterative manner, where an (N+1)^{th} layer of nanowires is formed/assembled on top an N^{th} layer of nanowires, where N is a natural number. In one embodiment, N is larger than one of the following: 2, 5, 10, 20, 50, and 100. In one embodiment, patterning of the substrate material in the (N+1)^{th} layer includes one or more of the following: nanoimprint lithography, photolithography, electron-beam lithography, interference lithography, self-aligned nanopatterning techniques, nanosphere lithography, and displacement talbot lithography. In one embodiment, etching of the substrate material in the (N+1)^{th} layer includes one or more of the following: MACE, Au MACE, Ru MACE, Pt MACE, vapor-phase MACE, liquid-phase MACE, reactive ion etching, and deep reactive ion etching.

In one embodiment, high aspect ratio nanowires 2604 in functional material (e.g., functional material 2602) is formed with lateral supports. In one embodiment, the nanopores are filled with a functional material (e.g., functional material 2602), such as boron. In one embodiment, the hard-anodized layers are selectively removed, leaving behind boron nanowires 2604, supported by lateral continuous layers of aluminum oxide. In one embodiment, the hard-anodized layers are selectively removed, leaving behind boron nanowires 2604, supported by lateral tethers of aluminum oxide.

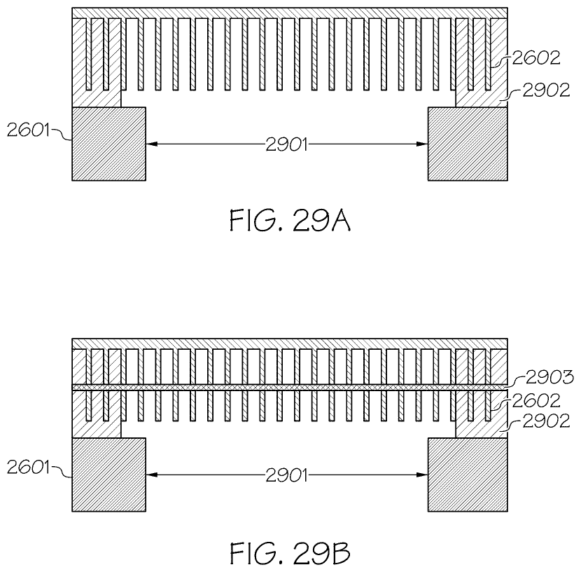

Referring now to FIG. 28, FIG. 28 is a flowchart of a method 2800 for forming nanowires of functional material in accordance with an embodiment of the present disclosure.

In step 2801, the base substrate is optionally coated with an adhesion promotor (e.g., titanium) followed by a high conductivity electrode material (e.g., gold) and optionally followed by a suitable valve metal (e.g., distinct from aluminum, such as tungsten).

In step 2802, aluminum is deposited on the top surface of the structure of step 2801, such as via CVD, ALD, e-beam deposition, electrodeposition, chemical deposition, etc., and/or bonding of the aluminum substrate (e.g., aluminum foil) to the starting substrate, such as via covalent bonding, anodic bonding, eutectic bonding, etc.

In step 2803, electropolishing of the aluminum surface is optionally performed, such as using a perchloric acid solution, to improve the surface roughness for the anodization step.

In step 2804, patterning (e.g., using nanoimprint lithography) and optionally performing a descum etch and pattern transfer to aluminum using aluminum etching.

In step 2805, a deep pore is created using aluminum anodization, such as by using an optionally high conductivity electrode. In one embodiment, the anodization is a single step anodization. In another embodiment, the anodization is a two-step anodization in which a first anodization creates defective pores that are removed using a suitable etchant, such as phosphoric acid, followed by a second anodization that utilizes the well-arranged scallops created after the first anodization to create well-structured deep pores. The anodization could also be performed in a pulsed manner to create hard and mild anodization regions.

In step 2806, a through-etch of the base material is performed, such as via DRIE.

In step 2807, titanium and gold and any residual aluminum and the AAO barrier layer from the bottom are removed, such as by using dilute phosphoric acid.

In step 2808, holes in the AAO layer are optionally expanded isotropically using a suitable dilute etchant (e.g., dilute phosphoric acid). Alternatively, and optionally, holes in the AAO layer are contracted using a suitable conformal coating of a sacrificial material (e.g., aluminum oxide, silicon dioxide, carbon, etc.) using CVD, ALD, etc.

If a pulse anodization technique is used, in one embodiment, hard anodized AAO is removed using a suitable etchant (e.g., phosphoric acid, HF, fluorine-containing plasmas, etc.), followed by deposition of lateral tether material (e.g., carbon, silicon dioxide, etc.) using a conformal deposition method (e.g., CVD, ALD, etc.) to an extent that the lateral pores get sealed, followed by deposition of functional material using CVD, ALD, etc. into nanopores, followed by optionally shrinking of the nanostructure size and/or tether size using a suitable etch technique (e.g., atomic layer etching, selective atomic layer etching, plasma etching, etc.).

If a pulse anodization technique is used, in another embodiment, hard anodized AAO is removed using a suitable etchant (e.g., phosphoric acid, HF, fluorine-containing plasmas, etc.) leaving behind continuous lateral tethers of mild anodized aluminum oxide, followed by optionally shrinking of the nanostructure size and/or tether size using a suitable etch technique (e.g., atomic layer etching, selective atomic layer etching, plasma etching, etc.).

If a pulse anodization technique is not used, in one embodiment, functional material is deposited into nanopores using CVD, ALD, etc., and then all aluminum oxide is removed using a suitable etchant (e.g., phosphoric acid), while implementing a suitable collapse mitigation technique. Once aluminum oxide has been fully removed, collapse mitigation is continuously performed until the functional material has fulfilled its intended function. Alternatively, the functional material nanostructures are allowed to collapse, and un-collapsed using a suitable collapse prevention method (e.g., nanowire charging method) when required.

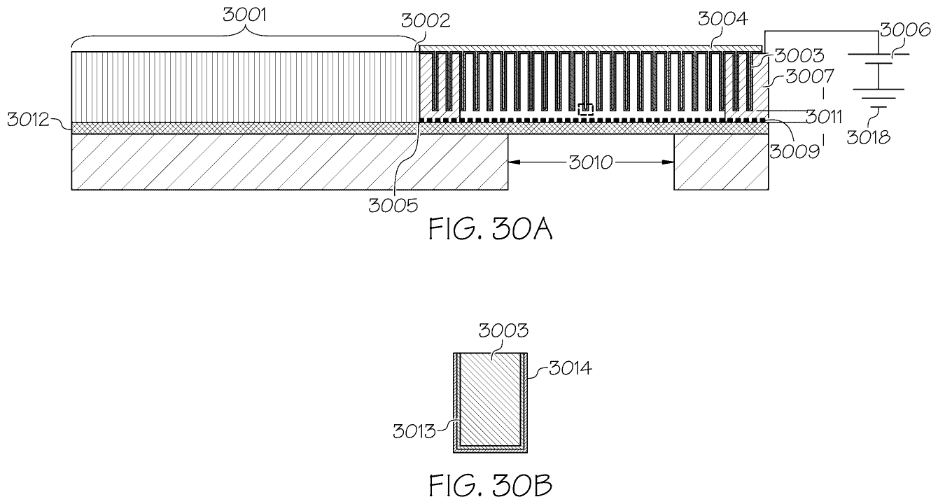

FIG. 29A illustrates the final structure using the method of FIG. 28 when the pulse anodization techniques are not utilized in accordance with an embodiment of the present disclosure. As shown in FIG. 29A, FIG. 29A highlights the area of interest 2901 as well as illustrates the residual aluminum oxide 2902 on the periphery on the area of interest 2901.

FIG. 29B illustrates the final structure using the method of FIG. 28 when pulse anodization techniques are utilized in accordance with an embodiment of the present disclosure. As shown in FIG. 29B, a lateral tether 2903 is utilized.

The following discusses collapse management of very high aspect ratio nanostructures.

High aspect ratio nanostructures generally require a collapse management method to ensure that the nanostructures, as fabricated, remain free-standing during operation. Potential modes of collapse could include lateral collapse (where the adhesive forces between neighboring nanostructures cause them to collapse), or ground collapse (where the adhesive forces between nanostructures and the base of the nanostructures cause them to collapse). In one embodiment, collapse management (which can include collapse prevention as well as un-collapsing collapsed nanostructures) is performed on dry nanostructures (for instance, during dry processing using techniques, such as plasma etching, vapor-phase MACE, vapor-liquid-solid growth, etc.). In one embodiment, collapse management (which can include collapse prevention as well as un-collapsing collapsed nanostructures) is performed on wet nanostructures (for instance, during wet processing of the nanostructures). In one embodiment, collapse management (which can include collapse prevention as well as un-collapsing collapsed nanostructures) is performed in high-vacuum (100 milli Pa or below). In one embodiment, collapse management (which can include collapse prevention as well as un-collapsing collapsed nanostructures) is performed in a low-vacuum (100 milli Pa or above). In one embodiment, collapse management (which can include collapse prevention as well as un-collapsing collapsed nanostructures) is performed at atmospheric pressure. In one embodiment, the nanostructures are comprised of nanowires.

In one embodiment, nanostructure collapse is mitigated by coating the surface of the nanostructures with a low-surface-energy coating so as to reduce the adhesive force (in the lateral and the ground collapse cases). Exemplary low surface-energy coatings (for instance, below 20 mN/m surface tension or below 15 mN/m or below 10 mN/m) include fluoropolymers (CₓF_{y}H_{z} where x, y∈[1, inf) and z∈[0, inf)).

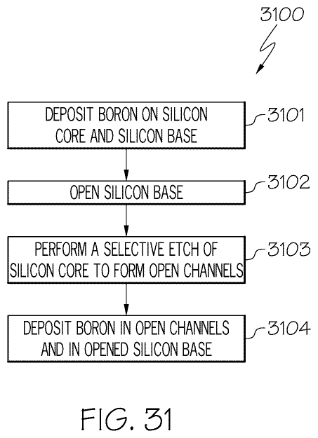

In one embodiment, nanostructure collapse is mitigated by charging the nanostructures with charges of the same polarity. In one embodiment, the charging is performed using a separate device that connects to the nanostructures, or alternatively a suitable integrated device (for instance, a capacitor, an integrated capacitor, an integrated metal insulator metal (MIM) capacitor, a battery, or an integrated battery). In one embodiment, the charging is performed while the nanowire fabrication is being performed, and optionally also during nanostructure usage. In one embodiment, non-conductive nanostructures are coated with a thin conductive coating to enhance charge redistribution among the nanostructures. An exemplary diagram for collapse prevention and/or un-collapsing collapsed nanostructures is discussed below in connection with FIGS. 30A-30B.

FIGS. 30A-30B illustrate a diagram for collapse prevention and/or un-collapsing collapsed nanostructures in accordance with an embodiment of the present disclosure.

As shown in FIG. 30A, FIG. 30A illustrates an optional integrated capacitor 3001 in AAO. In one embodiment, other optional charge sources include integrated batteries, solid-state batteries, etc.

Furthermore, FIG. 30A illustrates one electrode 3002 of integrated capacitor 3001 or other integrated charge source. In one embodiment, electrode 3002 is connected to the functional material nanostructures 3003 and optionally to the thin conductive layer coating nanostructures 3003. Furthermore, FIG. 30A illustrates functional material 3004 with nanostructures 3003 for which collapse prevention has been implemented or that could optionally be collapsed and need to be un-collapsed.

In one embodiment, the other electrode 3005 of integrated capacitor 3001 or other integrated charge sources is connected to either ground or to a conductive mesh 309 and/or to a conductive and transparent continuous layer.

In one embodiment, if an external high-voltage source 3006 is utilized, the cable or connection that connects source 3006 to the nanostructured sample 3007 could optionally be disposed once functional material 3004 has fulfilled its intended purposes. A new sample could come with its own dedicated disposable connector that attaches to the repeated-image power supply.

In one embodiment, external high-voltage power supply/source 3006 may correspond to a capacitor, a supercapacitor, battery, etc. In one embodiment, one end of power supply 3006 is connected to functional material nanostructures 3003 and optionally to the thin conductive layer coating nanostructures 3003.

In one embodiment, the other electrode of power supply 3006 is connected to either ground 3008 or to a conductive mesh 3009 and/or to a conductive and transparent continuous layer.

Additionally, FIG. 30A illustrates an optional electrically conductive mesh 3009. In one embodiment, the pore size of mesh 3009 is smaller than or equal to the size of the area of operational interest 3010.

In one embodiment, the residual thickness of AAO is large enough to prevent electrical breakdown due to a potentially high voltage difference between the top and bottom of the residual layer (see element 3011).

FIG. 30A additionally illustrates an optional thin continuous layer 3012 that is transparent in UV (ultraviolet) light and electrically conductive (e.g., SrNbO₃).

FIG. 30B illustrates a cross-section of the bottom portion of nanostructure 3003. As shown in FIG. 30B, in one embodiment, nanostructure has the material of boron. In one embodiment, a thin conductive layer 3013 (e.g., TiN, a doped polysilicon, a doped diamond) surrounds nanostructure 3003. In one embodiment, thin conductive layer 3013 and nanostructure 3003 are encapsulated by an encapsulation layer 3014 (e.g., SiO₂, carbon, BN). In one embodiment, encapsulation layer 3014 corresponds to a low-surface energy coating.

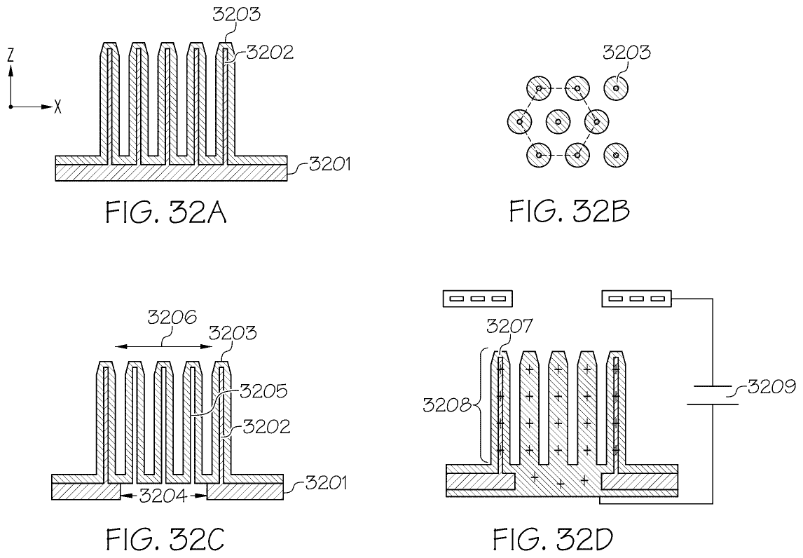

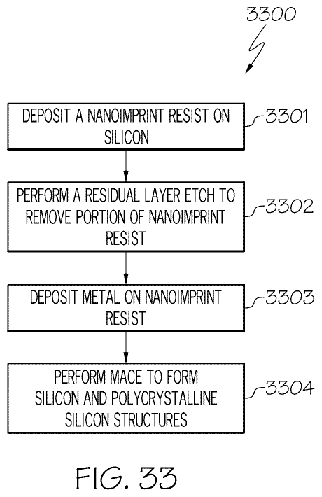

FIG. 31 is a flowchart of a method 3100 for forming nanowires of boron (or any other functional material) in accordance with an embodiment of the present disclosure. FIGS. 32A-32D depict cross-sectional views for forming nanowires of boron (or any other functional material) using the steps described in FIG. 31 in accordance with an embodiment of the present disclosure.

Referring to FIG. 31, in conjunction with FIGS. 32A-32D, boron 3203 is deposited on silicon core 3202 and silicon base 3201 as shown in FIG. 32A. FIG. 32B illustrates a cross-section of the deposited boron 3203.

In step 3102, silicon base 3201 is opened (opened space corresponds to element 3204), such as via DRIE, as shown in FIG. 32C.

In step 3103, a selective etch of silicon core 3202 is performed, such as by using XeF₂, to form open channels 3205 as shown in FIG. 32C. Furthermore, FIG. 32C illustrates the target laser irradiation area 3206. In one embodiment, such a selective etch includes one or more of the following: XeF₂ etch, fluoropolymer-based etch (utilizing CF₄, CHF₃), vapor HF, HF, plasma etch, wet etch, vapor-phase etch, crystallographic etch, KOH etch, DRIE, and RIE.

In step 3104, boron 3207 is deposited in the open channels 3205, such as via CVD, as shown in FIGS. 32C-32D. Furthermore, in one embodiment, boron 3207 is deposited in open space 3204 as shown in FIGS. 32C-32D. As result of such depositions, nanowires 3208 are formed. Furthermore, in one embodiment, nanowires 3208 with boron 3207 are optionally trimmed. Additionally, in one embodiment, an optional nanowire charging apparatus 3209 is utilized for inducing charges on nanowires 3208.

In one embodiment, the charge induced on the nanostructures (e.g., nanowires 3208) is such that the resulting force due to electrostatic repulsion between the nanostructures is sufficient to overcome adhesive forces trying to collapse the nanostructures or the adhesive forces already holding collapsed nanostructures together.

In one embodiment, charge induction into nanostructures (e.g., nanowires 3208) for the purpose of collapse management is performed using an electron-beam incident upon the nanostructures (e.g., nanowires 3208). In another embodiment, a strong light beam (for instance, a strong laser) is used to strip electrons from the nanostructures. The electron stripping could be transient, such that in the timescales that it takes for the electrons to flow back and rebalance charges, the transiently upright nanostructures have fulfilled their functional goal. The nanostructures could themselves be electrically insulating, or alternatively, be placed on an insulating holder to retain the charge transferred (via the methods mentioned previously).

As an option, a fluorine-based plasma removal of lateral support could be performed, while maintaining electrostatic repulsion between the nanowires.

If a core-shell approach is utilized (see FIGS. 26A-26C, 27A-27C), the central core, if it is retained in the final functional material nanowires, could be charged to prevent nanowire collapse.

An anneal step could be utilized, post-deposition of the functional material (core-shell approach of FIGS. 26A-26C, 27A-27C or the AAO-based approach of FIGS. 28 and 29A-29B), to reduce/remove residual strain in the nanostructures.

The following discusses the applications of the AE2 process.

In one embodiment, the AAO nanopore arrays are utilized to fabricate arrays of charge storage elements, with applications in DRAM, 3D NAND flash, supercapacitor, and battery fabrication.

Metal Assisted Chemical Etching (MACE) shows reliable etching only in single-crystal silicon, which limits its applications to a small number of front-end semiconductor device layers. The principles of the present disclosure extend the capabilities of MACE to polysilicon which, when combined with additional process steps, has the potential to create anodes for high capacity and flexible batteries. Polysilicon MACE also has potential applications to pattern for metal vias and deep trench capacitors used in semiconductor logic and memory devices if used with compatible polysilicon deposition methods and adapted CMOS-compatible MACE.

The principles of the present disclosure present a MACE wet etch of polysilicon that produces structure arrays with sub-50 nm resolution and anisotropic profile. The three demonstrated structures are pillars of 6:1 aspect ratio and 50 nm spacing for comparison to MACE literature, pillars of 30 nm spacing to establish resolution limitations of polysilicon etch, and a diamond pillar array with potential to fabricate holes with as low as 15 nm spacing.

Metal Assisted Chemical Etching (MACE) is a wet-etch technique that is uniquely suited to etching High-quality High-resolution (sub-100 nm, sub-50 nm, sub-20 nm) High aspect ratio (H3) nanostructures in single-crystal silicon. However, for several high-volume and cost-sensitive applications, such as optical elements for AR/VR, novel batteries and capacitors, etc., single-crystal silicon is not a substrate of choice. These applications require parallel processing of many unit products on large substrates to reduce the average cost per product. Roll-to-roll processing is ideally suited for such applications. However, single-crystal silicon is not easily grown on roll substrates. In this context, the ability to perform high-quality MACE on polysilicon (poly-MACE) could be highly relevant, since roll-to-roll deposition of polysilicon can be done routinely.

Outside of MACE on roll substrates, poly-MACE could potentially enable H3 nanostructures on non-silicon substrates, such as glass (especially display-grade glass which has applications in the AR/VR space). Poly-MACE could also be used to fabricate polysilicon-based nanostructures on top of existing semiconductor devices, which could have applications in the emerging space of Heterogenous Integration (HI) and advanced packaging.

MACE for polysilicon is currently in a nascent state. The poor quality of polysilicon MACE has been attributed to the presence of grain boundaries in polysilicon, which can increase the tendency of the catalyst to wander in uncontrollable ways during the etch. An approach proposed by Kim et al., “Self-Anchored Catalyst Interface Enables Ordered Via Array Formation from Submicrometer to Millimeter Scale for Polycrystalline and Single-Crystalline Silicon,” ACS Applied Materials and Interfaces, Vol. 10, No. 10, 2018, pp. 9116-9122, can produce polysilicon vias down to ˜400 nm diameter (1-micrometer pitch). However, the 400 nm diameter vias seem to have a large amount of taper, and it seems unlikely that this method would scale well to sub-100 nm high-aspect-ratio nanostructures.

The principles of the present disclosure enable high-quality high-resolution (sub-100 nm, sub-50 nm, sub-20 nm) high-aspect-ratio MACE of polysilicon, enabled by following three process steps: (1) planarization of deposited polysilicon, to levels that allow for high-resolution patterning; (2) high-resolution patterning using Nano Imprint Lithography (NIL); and (3) high aspect ratio etching of NIL patterns in polysilicon using a MACE process. The combination of the above three process steps is referred to herein as “poly-MACE.”

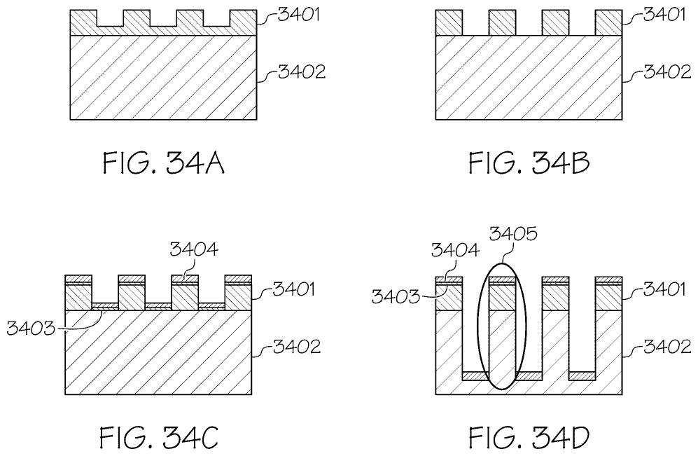

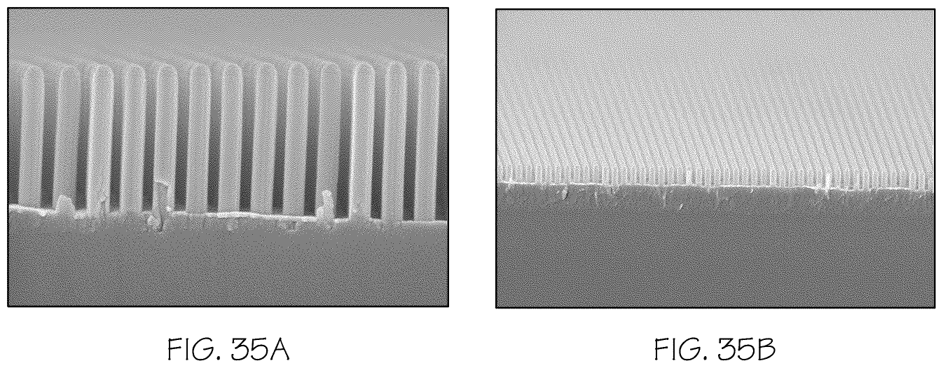

In one embodiment, a 1-micrometer-thick undoped polysilicon, deposited on polished <100> single-crystal silicon p-type wafers, was utilized to demonstrate poly-MACE. Polysilicon was deposited with low-pressure chemical vapor deposition (LPCVD) at 620° C., followed by chemical mechanical polishing (CMP) of the film. For comparison purposes, single-crystal MACE samples were also fabricated, using <100> p-type silicon wafers, with the MACE preformed using a previously-reported technique employing gold as the MACE catalyst. All experiments followed the same overall process flow discussed below in connection with FIGS. 33 and 34A-34D. FIG. 33 is a flowchart of a method 3300 for fabricating silicon and polycrystalline silicon structures using MACE and a metal break technique in accordance with an embodiment of the present disclosure. FIGS. 34A-34D depict the cross-sectional views for fabricating silicon and polycrystalline silicon structures using MACE and a metal break technique using the steps described in FIG. 33 in accordance with an embodiment of the present disclosure.

Referring to FIG. 33, in conjunction with FIGS. 34A-34D, in step 3301, a nanoimprint resist 3401 is deposited on silicon 3402 (e.g., single-crystal silicon, polysilicon film on silicon) as illustrated in FIG. 34A.

In step 3302, a residual layer etch is performed to remove a portion of nanoimprint resist 3401 as shown in FIG. 34B.

In step 3303, metal is deposited on nanoimprint resist 3401. In one embodiment, titanium 3403 followed by a gold catalyst 3404 are deposited on nanoimprint resist 3401 as shown in FIG. 34C.

In step 3304, MACE is performed to form silicon and polycrystalline silicon structures 3405 as shown in FIG. 34D.

In one embodiment, wafers were patterned using Jet-and-Flash Imprint Lithography (J-FIL), which is a form of Nano Imprint Lithography (NIL). In one embodiment, an Imprio-1100 wafer-scale J-FIL tool is utilized for this purpose. In one embodiment, the NIL template is fabricated by a commercial photomask vendor, Dai Nippon Print (DNP) of Japan. In one embodiment, J-FIL produces a residual layer that was removed with an oxygen and argon based RIE process.

In one embodiment, thin films of titanium 3403 and gold 3404 are deposited using a vacuum-based electron-beam evaporator (CHA Industries, Inc). Gold functions as the catalyst for MACE process. Titanium acts as an adhesion promoter to prevent gold delamination at the beginning of the etch. In one embodiment, the thickness of titanium 3403 is between 05 and 2 nm and the thickness of gold 3404 is between 10 and 15 nm. In one embodiment, deposition of titanium is conducted at a rate of 0.1 Å/s, and the deposition of gold is conducted at a rate of 0.4 Å/s, both at a pressure of ˜5*10⁻⁶ torr.

In one embodiment, MACE etchants comprise hydrofluoric acid (HF), hydrogen peroxide (H₂O₂), and deionized (DI) water.

In one embodiment, MACE of both single-crystal silicon and polysilicon was performed using an etchant composition of 4 HF:1 H₂O₂:4 H₂O (by volume), at room temperature in an acid bench located in a class 100 cleanroom.

Cross-sectional SEM characterization was performed using a ZEISS Neon 40 Scanning Electron Microscope (SEM), and top-down SEM using a Scios 2HiVac Dual beam SEM System. Sample preparation of polysilicon samples include deposition of a 2 nm gold-palladium alloy, using an Emitech Sputter Coater K575X-SEM, to enhance image fidelity.

The results of implementing the method of FIG. 33 is discussed below.

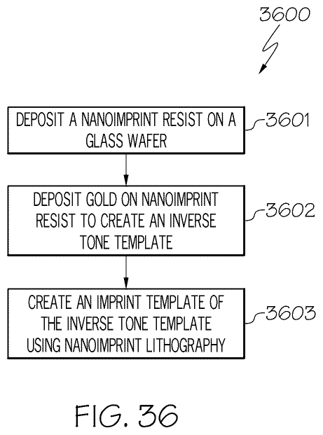

FIG. 35A is an SEM (scanning electron microscope) (scale bar is 200 nm) image of the cross-section of the polysilicon pillars (e.g., structures 3405) in accordance with an embodiment of the present disclosure. FIG. 35B is an SEM image (scale bar is 1 micrometer) of the tilted cross-section of the polysilicon pillars (e.g., structures 3405) in accordance with an embodiment of the present disclosure.

FIGS. 35A-35B depict such pillars with an aspect ratio of 6:1, created in polysilicon, using NIL-based patterning, and with the PoR (process-of-record) for single-crystal silicon modified for polysilicon.

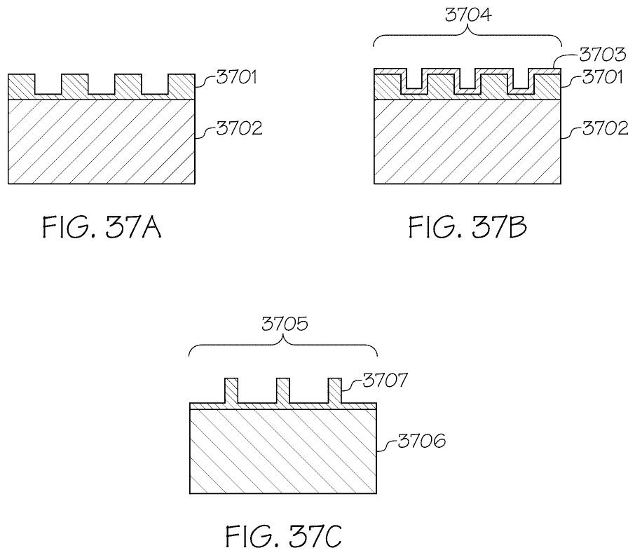

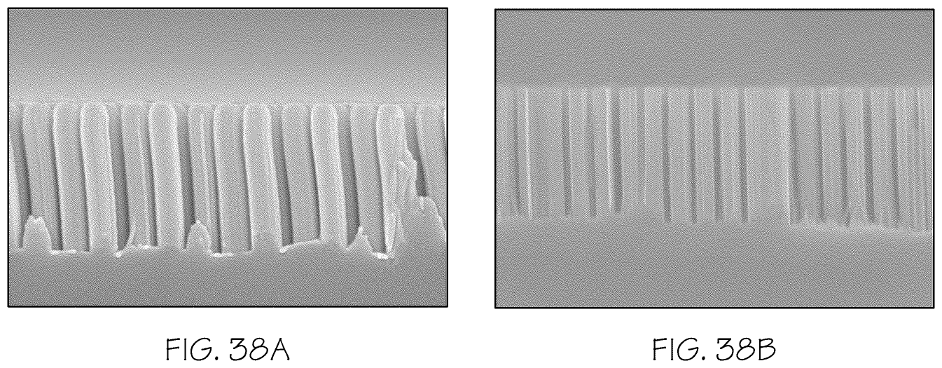

Referring now to FIG. 36, FIG. 36 is a flowchart of a method for creating an imprint template of inverse tone in accordance with an embodiment of the present disclosure. FIGS. 37A-37C depict the cross-sectional views for creating an imprint template of inverse tone using the steps described in FIG. 36 in accordance with an embodiment of the present disclosure.

Referring to FIG. 36, in conjunction with FIGS. 37A-37C, in step 3601, a nanoimprint resist 3701 is deposited on a glass wafer 3702 as illustrated in FIG. 37A.

In step 3602, gold 3703 is deposited on nanoimprint resist 3701 to create an inverse tone template 3704 as illustrated in FIG. 37B. In one embodiment, such a deposition is performed via sputtering.

In step 3603, inverse tone template 3704 is utilized to create an imprint template 3705 of the inverse tone template 3704 on a substrate 3706 (e.g., single crystal silicon, polysilicon film on silicon) using imprint lithography as illustrated in FIG. 37C. As further illustrated in FIG. 37C, polysilicon pillars 3707 are formed.

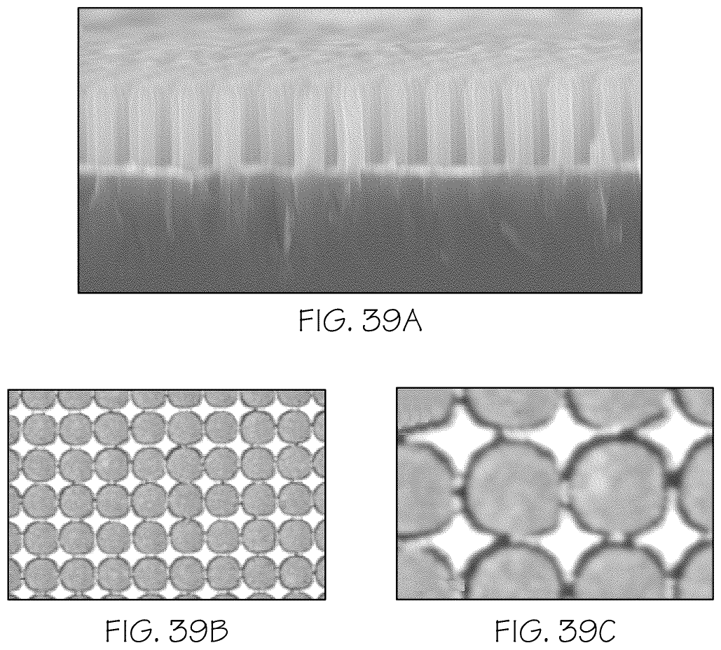

In one embodiment, the fabrication of the polysilicon pillars (e.g., polysilicon pillars 3707) of 30 nm spacing utilized a modified imprint step (creating a template of inverse tone 3704) that increased the diameter of pillar resist caps from their initial value of 150 nm to 170 nm. This modification may introduce surface defects in the patterned catalyst layer, which results in vertical striations after MACE as shown in FIG. 38A. This occurred in single-crystal silicon as shown in FIG. 38B. Therefore, such striations are an artifact of the modified imprint process and not of the polysilicon MACE process. FIG. 38A is an SEM image (scale bar of 200 nm) of the cross-section of the polysilicon pillars (e.g., polysilicon pillars 3707) with approximately 170 nm spacing in accordance with an embodiment of the present disclosure. FIG. 38B is an SEM image (scale bar of 200 nm) of the cross-section of the polysilicon pillars (e.g., polysilicon pillars 3707) with approximately 30 nm spacing after removal of the resist caps in accordance with an embodiment of the present disclosure.

The following discusses diamond-shaped polysilicon pillars.

Pillars with diamond-shaped cross-sections were fabricated using the method of FIG. 36 to investigate the resolution limits of polysilicon MACE, and to further compare MACE etch quality between polysilicon and silicon. It is worth noting that etching of diamond-shaped pillars also results in the creation of complementary circular-shaped-holes (that are connected using tethers). Thus, the ability to etch diamond-shaped pillars has important implications for etching high aspect ratio vias and holes, for instance for DRAM structures. Etching isolated holes using MACE is generally challenging since isolated catalyst islands are subject to drift. Additionally, etchant transport becomes increasingly problematic with increasing etch depth. High aspect ratio holes in single-crystal silicon have been achieved with MACE previously. However, these are limited in dimension. Holes in polysilicon have also been etched with MACE previously. However, these exhibit common etch defects. such as profile taper and sidewall roughness.

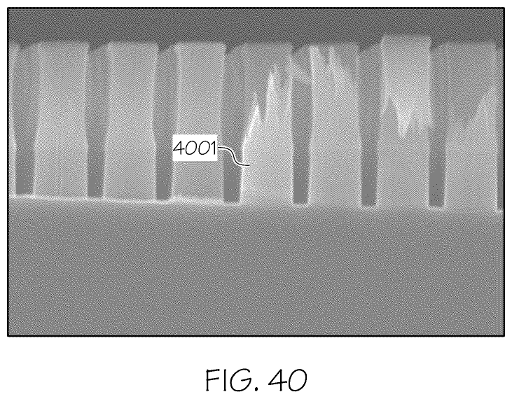

FIG. 39A illustrates a cross-sectional SEM image (scale bar of 400 nm) of the polysilicon diamond pillars fabricated using MACE using the steps of FIG. 36 in accordance with an embodiment of the present disclosure. FIG. 39B illustrates a top down SEM image (scale bar of 500 nm) of the polysilicon diamond pillars fabricated using MACE using the steps of FIG. 36 in accordance with an embodiment of the present disclosure. FIG. 39C illustrates a top down SEM image (scale bar of 100 nm) of the polysilicon diamond pillars fabricated using MACE using the steps of FIG. 36 in accordance with an embodiment of the present disclosure.

In one embodiment, in order to enable patterning using NIL, CMP of polysilicon was incorporated to minimize surface roughness of the deposited film. As-deposited polysilicon films often have high surface roughness, reportedly up to 580 Å for 11 μm thick films, which seems to negatively affect the morphology of NIL resist caps after the residual layer etch. Defects in resist cap morphology lead to defects in the catalyst layer, which finally lead to side wall vertical striations after MACE. CMP is able to reduce the extent of these defects significantly, but some amount of sidewall striations remain, nonetheless. This effect of CMP on polysilicon etching, where the CMP reduces but does not completely eliminate sidewall striations, is seen in reactive ion etch as well.

In one embodiment, the principles of the present disclosure utilize commercial-grade NIL, which allows the creation of patterns with long-range order as well as good critical dimension uniformity in the resulting nanostructures.

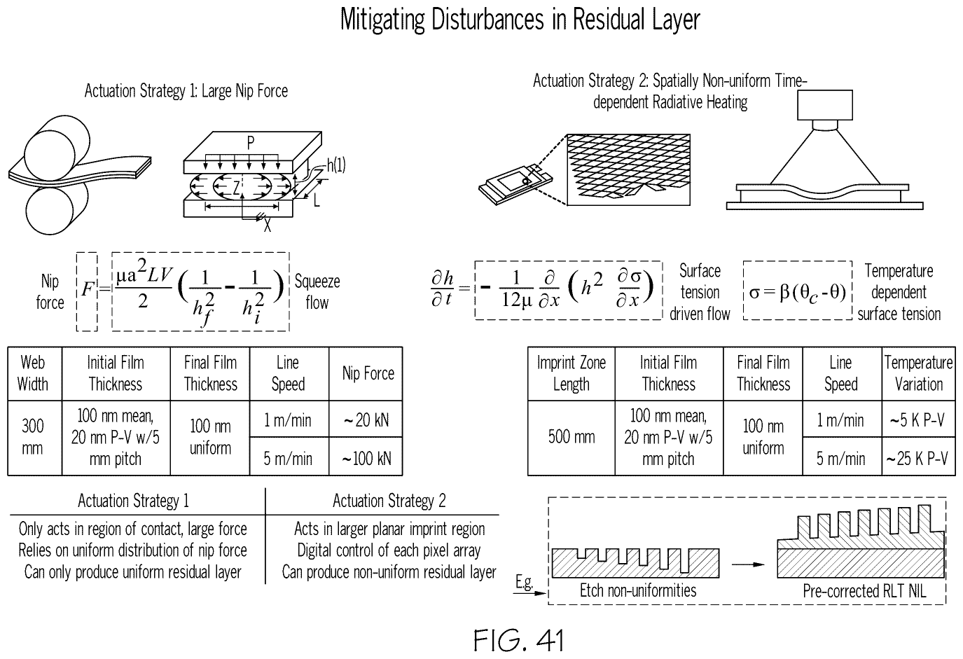

In one embodiment, a longer etch was conducted to examine MACE at the interface of polysilicon and silicon to further investigate poly-MACE. Pillars of 150 nm spacing did not maintain structural integrity and broke at the apparent material interface. However, fins of 150 nm width etched successfully. SEM characterization of the resulting polysilicon-silicon stack showed a tapered polysilicon profile, as shown in FIG. 40.

FIG. 40 is a cross-section SEM (scale bar of 800 nm) of fins 4001 etched past the polysilicon film interface with silicon in accordance with an embodiment of the present disclosure. In one embodiment, such fins 4001 are 150 nm (width) by 450 nm (height) in dimension.

The taper likely does not result from the MACE etch itself, but rather from intrinsic residual stresses near the material interface. It has been shown that the internal stresses of polycrystalline thin films are highly dependent on film deposition conditions. The amount of taper near the interface could potentially be reduced by performing LPCVD deposition of polysilicon at a higher temperature or by a post-deposition high-temperature anneal. For instance, an anneal of 1100° C. has been shown to reduce intrinsic stress of polysilicon films to near zero from 350 MPa compressive intrinsic stress. It is noted that LPCVD polysilicon films were deposited at a relatively low temperature of 620° C., and were not annealed following deposition.

Hence, the principles of the present disclosure enable reliable etching of high aspect ratio structures in polysilicon that are not compromised by crystal grain boundaries and that do not exhibit spurious porosity (which is achieved through careful tuning of the etch chemistry). The etch is enabled by the following three techniques: (1) reduction of surface-roughness in as-deposited polysilicon, to levels that allow high-resolution patterning; (2) high-resolution patterning using Nano Imprint Lithography (NIL); and (3) high aspect ratio etching of NIL patterns in polysilicon using a MACE process.

In one embodiment, by combining the principles of the present disclosure with the high-resolution patterning capabilities of NIL in roll substrates and plasma-based substrate planarization techniques, new avenues for deploying MACE in a roll-to-roll format for a variety of high-volume industrial applications that require high-quality high-resolution high aspect ratio nanostructures, ranging from optical elements for AR/VR, novel batteries and capacitors, etc., may potentially be opened. It is noted that Nanoimprint Lithography (NIL) is likely the only practical and cost-effective method for patterning arbitrary features at sub-50 nm feature sizes on roll substrates. Comparable optical techniques, such as photolithography (including EUV) and interference lithography, require high substrate site-flatness for high-resolution image formation on the substrate (proportional to λ/NA²; ˜150 nm for 0.33 NA EUV) and are also limited in field size making large-area high-speed patterning impractical. Such high levels of substrate site-flatness are not available on roll substrates.

High aspect ratio polysilicon structures are prone to profile defects, such as taper. Such defects likely arise from internal residual stresses in polysilicon during deposition. High-temperature processing usually removes these internal residual stresses. However, this might not be an option for a variety of applications that are limited to low-temperature processing due to the type of roll substrate employed (polymers roll substrates, for instance). Thus, stresses can be mitigated using polysilicon deposited at lower temperatures (sub-400° C., sub-200° C., or sub-150° C., or sub-100° C.). Exemplary options include wire chemical vapor deposition, PECVD (Plasma Enhanced CVD), etc. In some cases, deposition of amorphous silicon may be needed and the MACE process can be tuned for etching amorphous silicon.

In one embodiment, the principles of the present disclosure can be applied to polycrystalline silicon films that are deposited on a metallic film, wafer scale substrate, or flexible roll to roll substrate. In one embodiment, the principles of the present disclosure apply to polycrystalline silicon films deposited on copper films, single crystal wafer substrates, and polycarbonate roll to roll substrates. In one embodiment, the polycrystalline silicon film is planarized by Chemical Mechanical Polishing (CMP) or Inkjet-enabled Adaptive Planarization (IAP) to eliminate film surface roughness of >5 nm RMS. Planarization is followed by deposition of a metal catalyst film and/or imprint lithography.

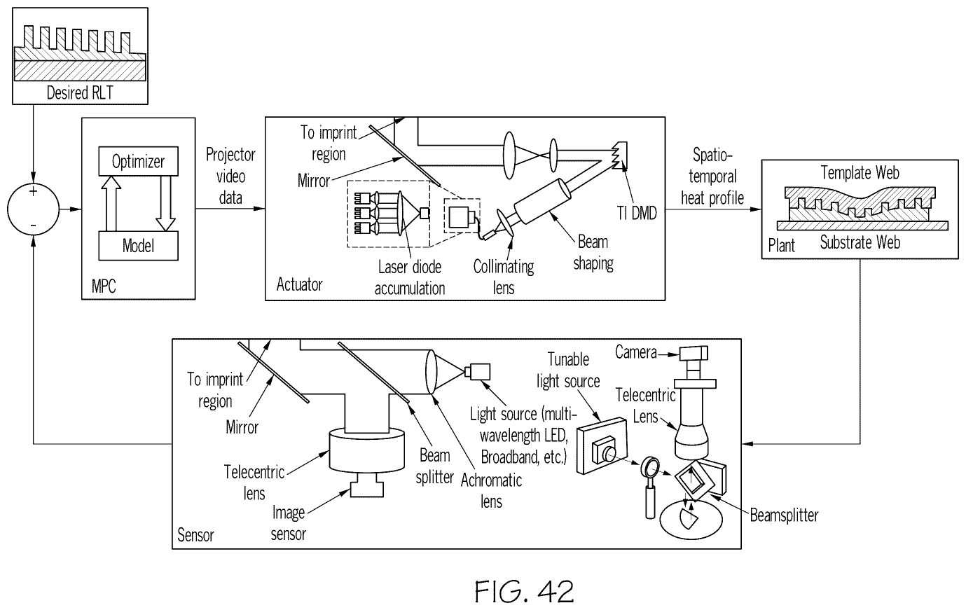

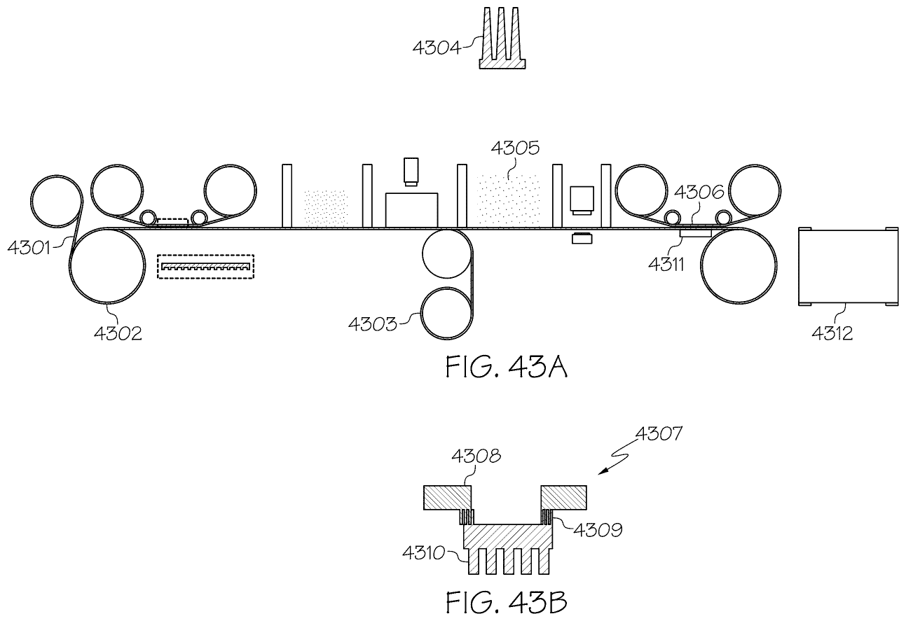

In one embodiment, patterning of the metal catalyst is performed in one of two ways: etching of a metal catalyst film or the “metal break” technique. Both means of catalyst patterning result in localized areas in which metal catalyst is in direct contact with the polycrystalline silicon film. In one embodiment, MACE of polycrystalline silicon occurs at the sites where the metal catalyst is in contact with the material. One means is through patterning of a metal catalyst film that exists under imprint resist. The catalyst film is deposited on the polycrystalline silicon film, followed by imprint lithography and subsequent residual layer etch. The residual layer etch exposes areas of the metal catalyst film which are etched with diluted ceric ammonium nitrate or potassium iodide. The remaining imprint resist is removed with piranha, a mixture of sulfuric acid and hydrogen peroxide. Removal of the resist exposes patterned metal catalyst, in which the metal catalyst is in contact with the polycrystalline silicon film. Another means of metal catalyst patterning is “metal-break” in which catalyst deposition occurs after lithography and metal catalyst conforms to imprint resist. After producing imprint resist caps with residual layer etch, the catalyst metal is deposited through electron beam evaporation. There is a break in the deposited metal catalyst layer that occurs at the site of exposed polycrystalline silicon and imprint resist caps, which enables etchant transport to desired etch sites. In one embodiment, the lithography technique mentioned above could be roll-to-roll imprint lithography. In one embodiment, resist coating for the lithography process is performed using one or more of the following methods: inkjetting, slot-die coating, knife-edge coating, etc. In one embodiment, evaporation of an optional solvent in the resist is performed to reduce the thickness of the coated resist film. Thickness variation in the residual layer (after solvent evaporation), due to uneven evaporation, could be mitigated by monitoring the temperature profile of the coated layer (for instance, using a thermal imager), and utilizing inverse modeling and thermal actuation methods to compensate the uneven evaporation as illustrated in FIGS. 41 and 42. FIG. 41 illustrates mitigating disturbances in a residual layer in accordance with an embodiment of the present disclosure. FIG. 42 illustrates an in-situ monitoring and control process in accordance with an embodiment of the present disclosure.

In one embodiment, the metal catalyst is one or more (a mixture) of gold, platinum, palladium, ruthenium, carbon, chromium, silver, titanium, etc. In one embodiment, the etchant used to produce an anisotropic etch of polycrystalline silicon is comprised of hydrofluoric acid, hydrogen peroxide, and deionized water. In one embodiment, the composition of the etchant is 4 parts HF, 1 part hydrogen peroxide, and 4 parts water, all by volume. In one embodiment, the prior composition could be diluted using water. In one embodiment, this is performed to improve control over etch parameters, such as etch rate, porosity, etc. In one embodiment, the composition of the etchant is 4 parts HF, 1 part hydrogen peroxide, and 20 parts water, all by volume.

As previously discussed, in connection with FIGS. 3A-3F, in one embodiment, high aspect ratio holes are created in valve metal 302. In one embodiment. a seed pattern is first created on the surface of valve metal 302. In one embodiment, the seed pattern is created using a combination of nanoimprint lithography and etching (which could be a wet or dry etch). Subsequently, valve metal 302 is anodized in the pore formation regime, where the time of the etch governs the depth of the holes. In one embodiment, the holes are tapered. In one embodiment, the taper is continuous. In another embodiment, the taper is in steps. In one embodiment, the taper is monotonic. In one embodiment, valve metal 302 is aluminum. In one embodiment, a functional material (e.g., functional material 306) is deposited post anodization into the high aspect ratio holes. In one embodiment, the deposition is performed using CVD, PECVD, LPCVD, APCVD, ALD, PVD, electrochemical deposition, etc.

It is noted that the tapering is produced by gradual variation of the etch conditions (electric field, current, temperature, etchant concentration, etc.) as the etch progresses. It should also be noted that the optional functional material for deposition in the high aspect ratio holes could be silicon, polysilicon, silicon nitride, silicon carbide, carbon, diamond, boron nitride, III-Vs (GaAs, GaN, etc.), metals, metal oxides, lithium, etc. or combinations thereof or materials of which the materials are a part of.

In one embodiment, the lithography technique utilized to create the seed pattern above is roll-to-roll imprint lithography. In one embodiment, resist coating for the lithography process is performed using one or more of the following methods: inkjetting, slot-die coating, knife-edge coating, etc. In one embodiment, evaporation of an optional solvent in the resist is performed to reduce the thickness of the coated resist film. Thickness variation in the residual layer (after solvent evaporation), due to uneven evaporation, could be mitigated by monitoring the temperature profile of the coated layer (for instance, using a thermal imager), and utilizing inverse modeling and thermal actuation methods to compensate the uneven evaporation as discussed in FIGS. 41 and 42.

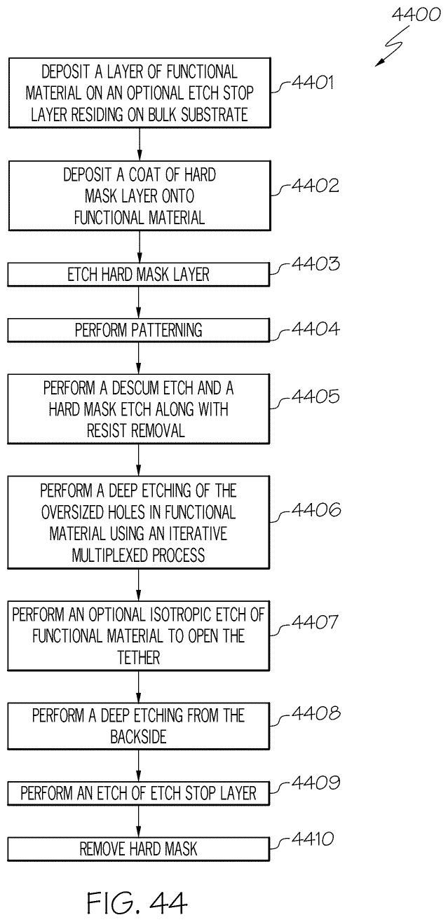

Referring now to FIG. 43A, FIG. 43A illustrates an exemplary AE2 process in accordance with an embodiment of the present disclosure.

As illustrated in FIG. 43A, the AE2 process includes the removal of frontside protective film (see element 4301).

The AE2 process further includes the tri-layer (or optionally bi-layer) roll comprised of an optional frontside protective film, a valve metal film (for instance, aluminum), and a backside protective film (for instance, polycarbonate) (see element 4302). In one embodiment, the thickness of the valve metal film is sub-1 mm, sub-100 μm, sub-50 μm, sub-20 μm, or sub-10 μm. In one embodiment, the thickness of the backside protective film is sub-1 mm, sub-100 μm, sub-50 μm, sub-20 μm, or sub-10 μm. In one embodiment, the backside protective film provides mechanical stability to the valve metal film during the R2R NIL step.

Furthermore, the AE2 process includes the removal of the backside protective film prior to functional material deposition (see element 4303).

Additionally, the AE2 process includes R2R AE2 with gentle taper and/or stepped taper in the nanostructures to enable a subsequent high aspect ratio deposition step (see element 4304).

Furthermore, the AE2 process includes R2R deposition of functional material (for instance, polysilicon, metals, gold, ruthenium, silicon oxide, silicon nitride, silicon carbide, polymers, carbon, diamond, and boron nitride) (se element 4305). An optional encapsulant (for instance, polysilicon, metals, gold, ruthenium, silicon oxide, silicon nitride, silicon carbide, polymers, carbon, diamond, boron nitride, and in general, a material resistant to the valve metal etchant) could be deposited prior to functional material deposition.

Additionally, the AE2 process includes an optional transfer of functional material to a holey carrier (see element 4306). In one embodiment, the carrier material is copper, polycarbonate or other polymers, with optional coatings of nickel, copper, polysilicon, or other substrates suitable for nanowire growth. In one embodiment, the carrier material is resistant to the valve metal wet etchant. In one embodiment, the transfer and attachment of the functional material to the holey carrier (shown in FIG. 43B) is performed using one or more of the following techniques: direct bonding, covalent bonding, anodic bonding, and bonding between two surfaces with dense nanowires/nanoforests. For the last part, nanowires/nanoforests would need to be grown on the backside of the functional material, and the frontside of the holey carrier.

Referring now to FIG. 43B, FIG. 43B illustrates a holey carrier 4307 in accordance with an embodiment of the present disclosure.

As shown in FIG. 43B, holey carrier 4307 includes holey carrier film 4308, a nanowire/nanoforest interface 4309 and nanostructured functional material 4310.

Returning to FIG. 43A, the AE process further includes wet/dry etchants (e.g., KOH) for the valve metal and valve metal oxide (see element 4311). In one embodiment, such a process step is used to remove the valve metal oxide scaffold, and any residual valve metal, after attachment to the optional carrier material.

FIG. 43A additionally illustrates a side view of the roller showing valve metal film that has been etched away near the center (see element 4312). In one embodiment, the portions near the edges provide mechanical connection and structural stability to the prior un-etched film.

Regarding collapse mitigation in nanostructures, in one embodiment, the nanostructures are comprised of nanopillars. In one embodiment, one or more of the nanostructures have undergone collapse. In one embodiment, one or more of the nanostructures are present in a vacuum environment. In one embodiment, an electron-beam incident from the front, side or backside of the nanostructures is used to induce charges in the nanostructures. The nanostructures would un-collapse once the amount of negative charge in the nanostructures is such that the electrostatic repulsion between like charges exceeds the adhesive forces keeping the nanostructures in a collapsed state. In another embodiment, a beam of laser (incident from the front, side or back) is utilized to strip electrons from the nanostructures, such that the nanostructures now contain a net positive change. In this case, the nanostructures would un-collapse once the amount of positive charge in the nanostructures is such that the electrostatic repulsion between like charges exceeds the adhesive forces keeping the nanostructures in a collapsed state.

In one embodiment, the un-collapsing methods described above could be utilized in parallel with other processes.

In one embodiment, assuming that a process exists for the fabrication of nanostructures on a substrate, and a new layer of substrate could be deposited on top of existing nanostructures, an iterative process to create an (N+1)^{th} layer of nanostructures on top of the N layers of nanostructures could be performed, where N is a natural number. In one embodiment, the nanostructure fabrication process utilizes one or more of the following methods: nanoimprint lithography, photolithography, electron-beam lithography, interference lithography, self-aligned nanopatterning techniques, etch techniques including MACE, reactive ion etching, deep reactive ion etching, deposition techniques (e.g., atomic layer deposition, chemical vapor deposition (CVD), plasma-enhanced CVD, sputtering, electron-beam deposition, physical deposition techniques and chemical deposition techniques), as well as growth techniques, such as vapor-liquid-solid (VLS) growth, vapor-solid (VS) growth, etc. In one embodiment, the deposition of the new layer of substrate is performed using one or more of the following methods: bonding (e.g., fusion bonding, direct bonding, hybrid bonding, anodic bonding, covalent bonding, etc.) followed by an optional backgrinding or etch back step or a thin film deposition technique, such as CVD, ALD, plasma-enhanced CVD, etc. In one embodiment, the substrate is one of the following materials: silicon, a silicon containing material, silicon oxide, spin-on oxide, silicon carbide, silicon nitride, polycrystalline silicon, amorphous silicon, aluminum oxide, metal, a polymer, a spin-on polymer, carbon, a carbon containing material, a metalloid, boron, boron carbide, and boron nitride. In one embodiment, the (N+1)^{th} layer of the nanostructures is aligned with respect to the N^{th} layer of nanostructures using a suitable alignment technique (such as using embedded moiré alignment marks, IR moiré alignment marks, offline alignment marks, alignment marks that require high-NA (over 0.3 NA, for instance) metrology, and alignment marks that require low-NA (sub-0.3 NA, for instance) metrology). In one embodiment, the alignment (or alternatively, overlay, or registration to a base layer) is better than one of: 100 nm (mean+3*sigma), 50 nm, 20 nm, 10 nm, 5 nm, 2 nm, and 1 nm.

In one embodiment, nanoimprint lithography is used to pattern the seed (or catalyst) layer used for the growth of nanostructures using a suitable growth technique, such as VLS and VS growth techniques, where the minimum feature size in the seed (or catalyst) layer is below one of the following: 500 nm, 200 nm, 100 nm, 50 nm, 20 nm, 10 nm, and 5 nm.

In one embodiment, during fabrication of the above-described nanostructures one or more of in-situ, ex-situ, in-line, and at-line metrology is performed to control or detect one of the following: nanostructure lateral dimension uniformity (CD uniformity), nanostructure height uniformity, nanostructure yield, and nanostructure collapse. For instance, the spatial variation in etch rate, or a proxy thereof (such as the unique spectral signature corresponding to a given etch feature height), is monitored in-situ. The metrology could, for instance, be achieved using one or more of the following: spectrophotometry, angle-resolved spectrophotometry, wavelength-resolved spectrophotometry, visible wavelength metrology, IR metrology, thermal mapping, spectrometry, optical imaging, ultrasound imaging, interferometry, white-light interferometry, and low-coherence interferometry. The metrology could either be reflective or transmissive. Furthermore, the metrology could either be done in real-time (synchronously) or asynchronously. In one embodiment, the metrology is performed on a wafer-scale basis (on one of the 50 mm, 75 mm, 100 mm, 150 mm, 200 mm, 250 mm, 300 mm, and 450 mm substrates), or on a roll-to-roll basis (on one of the 50 mm, 100 mm, 150 mm, 200 mm, 300 mm, 400 mm, and 500 mm-wide rolls).

In one embodiment, intermittent tethers are utilized to improve the stability of functional material high aspect ratio nanostructures.

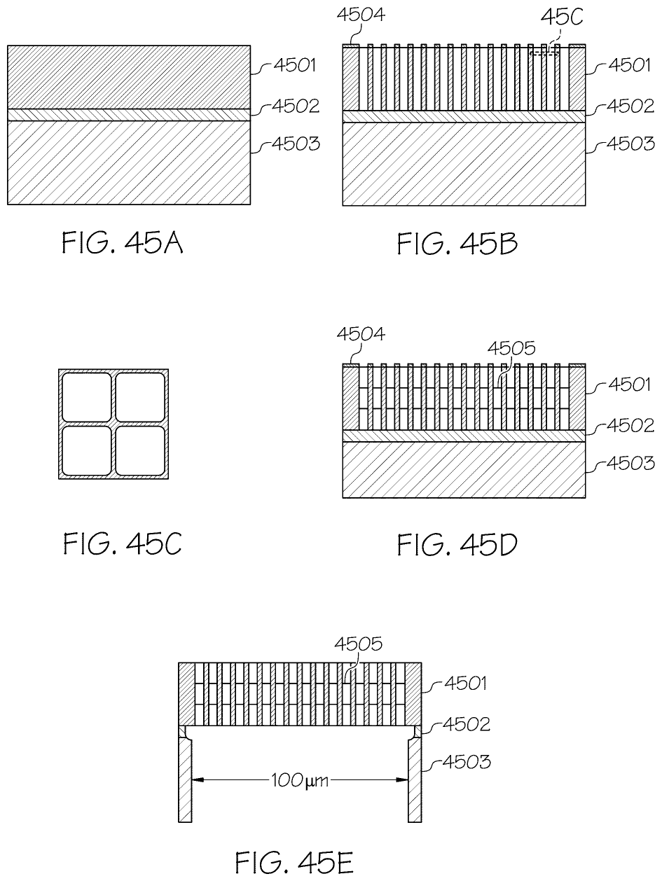

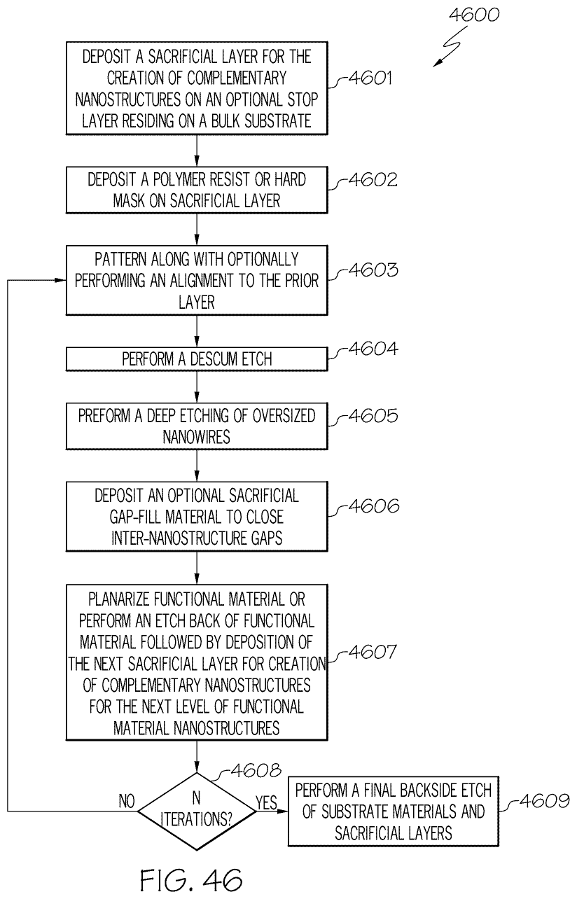

FIG. 44 is a flowchart of a method 4400 for the creation of functional material high aspect ratio nanostructures with tethers for stability in accordance with an embodiment of the present disclosure. FIGS. 45A-45E depict the cross-sectional views for the creation of functional material high aspect ratio nanostructures with tethers for stability using the steps described in FIG. 44 in accordance with an embodiment of the present disclosure.

Referring to FIG. 44, in conjunction with FIGS. 45A-45E, in step 4401, a layer of functional material 4501 is deposited on an optional etch stop layer 4502 residing on bulk substrate 4503 as shown in FIG. 45A. In one embodiment, functional material 4501 (e.g., boron) is coated onto optional etch stop layer 4502 using CVD, electron beam deposition, spin-coating, etc. with one of the following thicknesses: over 1 μm, over 5 μm, over 10 μm, over 50 μm, over 100 μm, over 200 μm and over 400 μm. In one embodiment, strain management techniques, such as intermittent anneal and deposition, are utilized to relieve residual strain during the coating or deposition processes.

In one embodiment, optional stop layer 4502 corresponds to silicon oxide, aluminum oxide, silicon carbide, boron nitride, boron, carbon, etc.

In one embodiment, bulk substrate 4503 corresponds to silicon, polymer, metal, etc.

In step 4402, a coat of hard mask layer 4504 is deposited onto functional material 4501 as shown in FIG. 45B.

In step 4403, hard mask layer 4504 is etched as shown in FIG. 45B.

In step 4404, patterning is performed (e.g., nanoimprint lithography and optionally with alignment to prior layer) as shown in FIG. 45B.

In step 4405, a descum etch and a hard mask etch along with resist removal are performed as shown in FIG. 45B.

In step 4406, a deep etching of the oversized holes in functional material 4501 is performed using an iterative multiplexed process, such as deep reactive ion etching (where a sidewall encapsulation step is followed by a first anisotropic and a second isotropic etch step) as shown in FIG. 45B. The top view of the resulting structure is shown in FIG. 45C.

In step 4407, an optional isotropic etch of functional material 4501 is performed to open the tether 4505 as shown in FIG. 45D.

In step 4408, a deep etching from the backside is performed as shown in FIG. 45E.

In step 4409, an etch of etch stop layer 4502 is performed, such as by using hydrogen fluoride (HF), as shown in FIG. 45E.

In step 4410, hard mask layer 4504 is removed as shown in FIG. 45E.

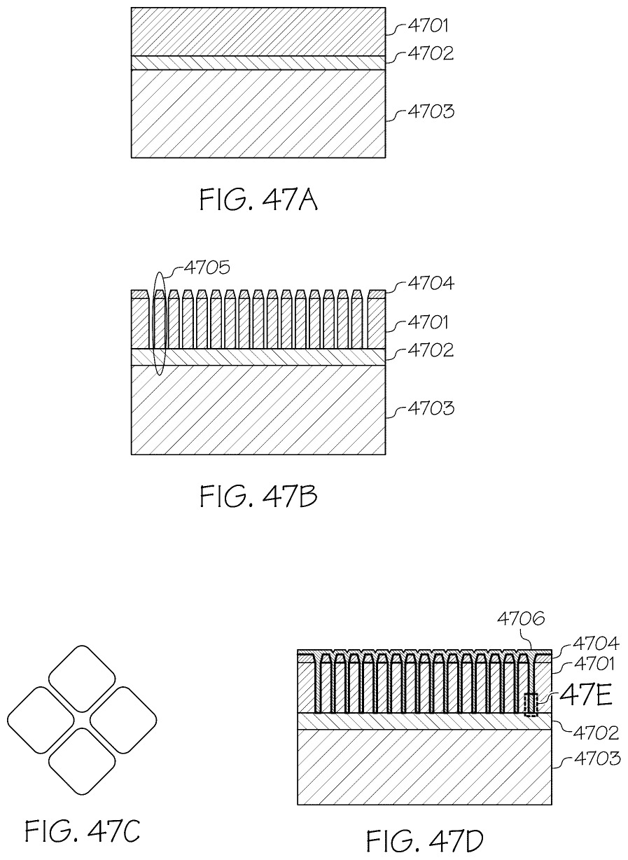

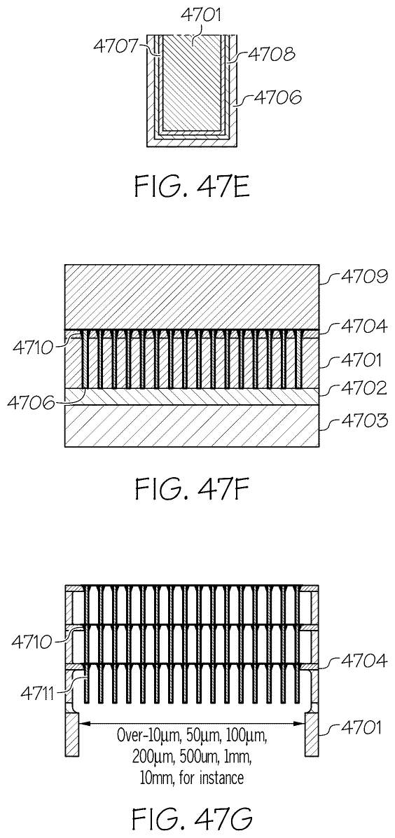

FIG. 46 is a flowchart of an alternative method 4600 for the creation of functional material high aspect ratio nanostructures with tethers for stability in accordance with an embodiment of the present disclosure. FIGS. 47A-47G depict the cross-sectional views for the creation of functional material high aspect ratio nanostructures with tethers for stability using the steps described in FIG. 46 in accordance with an embodiment of the present disclosure.

Referring to FIG. 46, in conjunction with FIG. 47A-47G, in step 4601, a sacrificial layer 4701 for the creation of complementary nanostructures is deposited on an optional stop layer 4702 (e.g., silicon oxide, aluminum oxide, silicon carbide, born oxide, boron, carbon, etc.) residing on bulk substrate 4703 (e.g., silicon, polymer, metal, etc.) as shown in FIG. 47A. In one embodiment, the complementary nanostructures have one of the following cross-sections: circular, square with rounded edges, and polygonal with rounded edges.

In step 4602, a polymer resist or hard mask 4704 is deposited on sacrificial layer 4701 as shown in FIG. 47B.

In step 4603, patterning is performed, such as by using nanoimprint lithography, along with optionally performing an alignment to the prior layer thereby forming nanowires 4705 as shown in FIG. 47B. A top view of complementary nanostructures, such as nanowires 4705, is shown in FIG. 47C.

Furthermore, FIG. 47C illustrates a polygonal cross-section (e.g., square, hexagon, octagon, etc.) with optionally rounded vertices. The polygonal cross-section reduces the amount of conformal deposition that would need to be performed in comparison to circular cross-section nanowires. It is noted that this geometry is easy to pattern using NIL while being very difficult to pattern using photolithography for nanoscale features. It is also noted that if e-beam patterning of closely-spaced features in the template turns out to be difficult, the features could be patterned using e-beam with larger gaps and the gaps subsequentially filled using a conformal deposition process (e.g., ALD) in the template itself.

In step 4604, a descum etch is performed as shown in FIG. 47B.

In step 4605, a deep etching (e.g., using MACE, RIE, etc.) of oversized nanowires 4705 is performed as shown in FIG. 47B. For instance, nanowires 4705 of 380 nm diameter on a 400 nm pitch may be formed.

In step 4606, an optional sacrificial gap-fill material 4706 (e.g., oxide, silicon oxide, aluminum oxide, carbon, silicon nitride, silicon carbide, polymer, fluoropolymer, etc.) is deposited to close inter-nanostructure gaps as shown in FIG. 47D. In one embodiment, such a deposition is followed by an optional encapsulant coating 4708 (see FIG. 47E), followed by functional material deposition. One or more of the following methods could be utilized for the above coatings: spin-coating of a reflowable polymer (e.g., polymer-derived BN, polyborazylene, boron-hydride based polymers, spin-on-glass, spin-on-carbon, spin-on-oxide, etc.), chemical vapor deposition or a conformal coating process (e.g., atomic layer deposition (ALD) of the functional material (e.g., boron, BN) or a templated growth process (e.g., using VLS/VS processes) using the optional sacrificial gap-fill material 4706 as the template for the growth and optionally the MACE catalyst as the catalyst for the growth process (after removing gap-fill material 4706 from the bottom of the etched nanowires 4705 using a suitable anisotropic etch process).

In one embodiment, gap-fill material 4706, encapsulation material 4708 and functional material 4701 include one or more of the following: silicon, a silicon containing material, silicon oxide, spin-on oxide, silicon carbide, silicon nitride, polycrystalline silicon, amorphous silicon, aluminum oxide, metal, a polymer, a spin-on polymer, carbon, a carbon containing material, a metalloid, boron, boron carbide, boron nitride, polymer-derived BN, polyborazylene, boron-hydride-based polymers, spin-on-glass, spin-on-carbon, spin-on-oxide, TiN, diamond, and CVD diamond.

FIG. 47E illustrates an optional thin conductive layer 4707 as doped poly silicon or doped BN or doped diamond or TiN.

In step 4607, functional material 4701 is planarized, such as by using chemical mechanical planarization, or an etch back of functional material 4701 is performed, followed by deposition of the next sacrificial layer 4709 for the creation of complementary nanostructures 4705 (e.g., polysilicon) for the next level of functional material nanostructures 4705 as shown in FIG. 47F.

In one embodiment, the shape of the template and/or the physical component of the descum etch process can be used to optimize the sidewall slope of the imprint resist posts such that the functional material planarization leaves behind thin lateral tethers 4710 as shown in FIG. 47F. Alternatively, during the patterning step, a first lithography and a short first etch (e.g., MACE) are performed, followed by a conformal coating step (e.g., using ALD of a sacrificial material, such as aluminum oxide) to expand the etched nanostructure diameter, followed by a self-aligned catalyst deposition and deep etch (e.g., using MAC). As a result, lateral tethers 4710 of functional material 4701 would be created after the planarization step.

In step 4608, a determination is made as to whether N (where N is a positive integer number) iterations of steps 4603-4607 have occurred. If not, then patterning is performed in step 4603.

If, however, N iterations of steps 4603-4607 have occurred, then, in step 4609, a final backside etch of substrate materials (e.g., bulk substrate 4703) and sacrificial layers (e.g., sacrificial layer 4701) are performed resulting in the structure shown in FIG. 47G, which includes multi-level functional material nanowires 4711.

It is noted that the process (method 4600) can be used for the deposition of arbitrary functional materials with arbitrary optional encapsulants to prevent oxidation or chemical corrosion of the functional material (e.g., functional material 4701).

In one embodiment, an oxide scaffold is kept around the filled boron until just prior to laser irradiation for the purpose of keeping the fragile boron nanowires stable against vibration during transportation, etc.

In one embodiment, a voltage/charge is applied to the functional material nanostructure (e.g., nanostructure 4711), during or immediately after fabrication, to not necessarily prevent collapse, but to prevent entangling during the fabrication steps. Subsequently, prior to usage of the functional material nanostructures (e.g., nanostructures 4711), a higher voltage or charge could be applied to un-collapse the potentially collapsed nanostructures. In one embodiment, the nanostructure surface could be treated with a low-surface energy material, such as fluoropolymers, to reduce their tendency to collapse or to entangle. In one embodiment, the nanostructures (e.g., nanostructures 4711) could intentionally be fabricated to be oversized to improve mechanical stability, and subsequently, just prior to use, could be isotropically etched to reduce their size to the required correct dimension.

In one embodiment, a single layer of functional material nanostructures (e.g., nanostructures 4711) is first created using a suitable method (e.g., growth, direct etch of functional material, etc.), which is then fully encapsulated by coating a sacrificial material (using spin-coating, for instance) to stabilize the nanostructures, followed by coating of a second layer of functional material and fabrication of nanostructures on this second layer (using an aligned lithography step to the first layer), and so on as before. In the end, the sacrificial material could be removed to reveal high aspect ratio nanostructures.

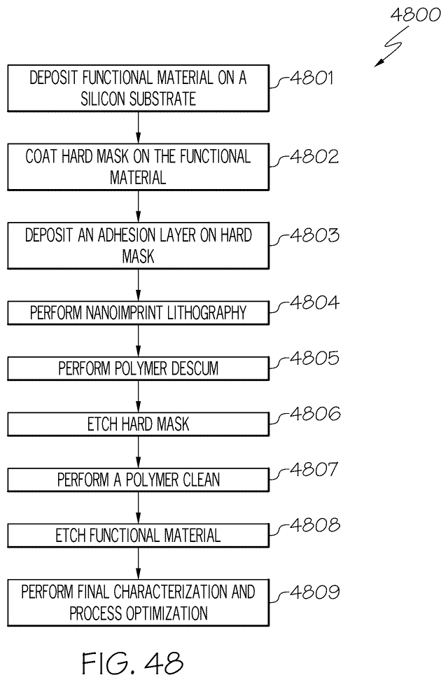

Referring to FIG. 48, FIG. 48 illustrates a method 4800 for an RIE-based process for the creation of functional material nanostructures in accordance with an embodiment of the present disclosure.

In step 4801, functional material is deposited on a silicon substrate.

In step 4802, a hard mask is coated on the functional material.

In step 4803, an adhesion layer is deposited on the hard mask.

In step 4804, nanoimprint lithography is performed.

In step 4805, a polymer descum is performed.

In step 4806, the hard mask is etched.

In step 4807, a polymer clean is performed.

In step 4808, the functional material is etched.

In step 4809, final characterization and process optimization are performed.

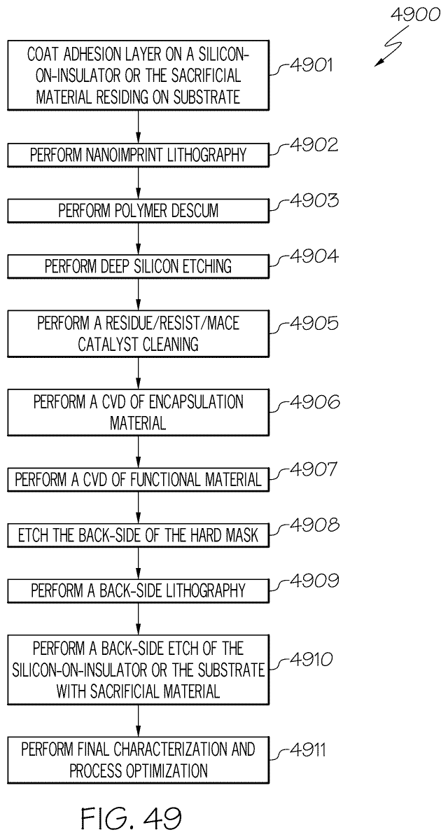

Referring to FIG. 49, FIG. 49 is a flowchart of a method 4900 for creating functional material nanostructures using CVD-based hole-filling in accordance with an embodiment of the present disclosure.

In step 4901, an adhesion layer is coated on a silicon-on-insulator or the sacrificial material residing on a substrate.

In step 4902, nanoimprint lithography (or other type of lithography) is performed.

In step 4903, a polymer descum is performed.

In step 4904, a deep silicon etching is performed.

In step 4905, a residue/resist/MACE catalyst cleaning are performed.

In step 4906, a CVD of encapsulation material is performed.

In step 4907, a CVD of functional material is performed.

In step 4908, the back-side of the hard mask is etched.

In step 4909, a back-side lithography is performed.

In step 4910, a back-side etch of the silicon-on-insulator or the substrate with sacrificial material is performed.

In step 4911, final characterization and process optimization are performed.

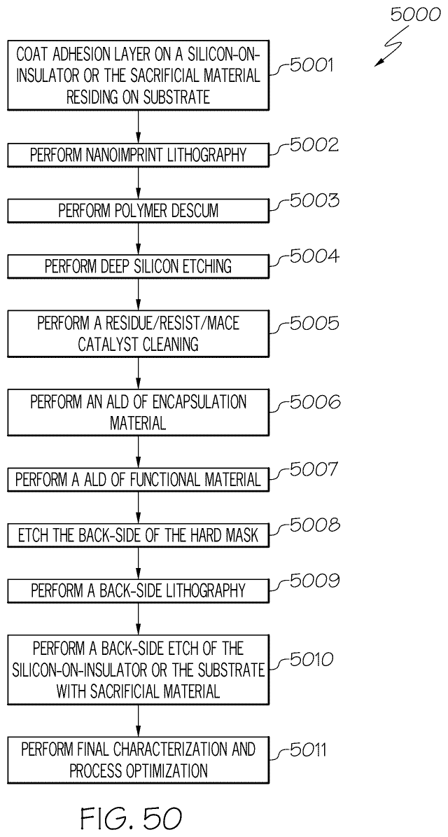

Referring to FIG. 50, FIG. 50 is a flowchart of a method 5000 for creating functional material nanostructures using ALD-based hole filling in accordance with an embodiment of the present disclosure.

In step 5001, an adhesion layer is coated on a silicon-on-insulator or the sacrificial material residing on a substrate.

In step 5002, nanoimprint lithography (or other type of lithography) is performed.

In step 5003, a polymer descum is performed.

In step 5004, a deep silicon etching is performed.

In step 5005, a residue/resist/MACE catalyst cleaning are performed.

In step 5006, an ALD of encapsulation material is performed.

In step 5007, an ALD of functional material is performed.

In step 5008, the back-side of the hard mask is etched.

In step 5009, a back-side lithography is performed.

In step 5010, a back-side etch of the silicon-on-insulator or the substrate with sacrificial material is performed.

In step 5011, final characterization and process optimization are performed.

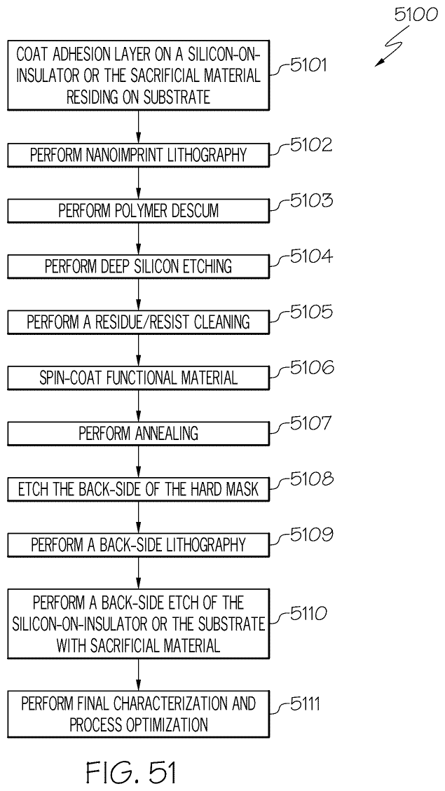

Referring to FIG. 51, FIG. 51 is a flowchart of a method 5100 for spin-coating of functional material containing polymer for hole filling in accordance with an embodiment of the present disclosure.

In step 5101, an adhesion layer is coated on a silicon-on-insulator or the sacrificial material residing on a substrate.

In step 5102, nanoimprint lithography (or other type of lithography) is performed.

In step 5103, a polymer descum is performed.

In step 5104, a deep silicon etching is performed.

In step 5105, a residue/resist cleaning are performed.

In step 5106, functional material, which contains polymers, is spin-coated.

In step 5107, annealing is performed.

In step 5108, the back-side of the hard mask is etched.

In step 5109, a back-side lithography is performed.

In step 5110, a back-side etch of the silicon-on-insulator or the substrate with sacrificial material is performed.

In step 5111, final characterization and process optimization are performed.

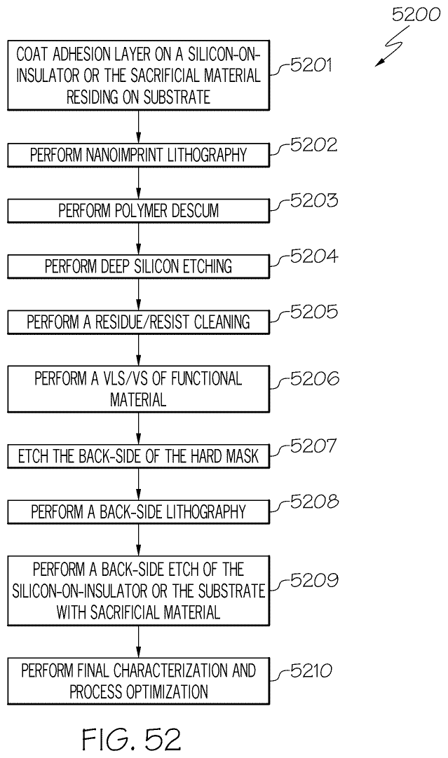

Referring to FIG. 52, FIG. 52 is a flowchart of a method 5200 for a confined/templated VLS/VS functional material growth in accordance with an embodiment of the present disclosure.

In step 5201, an adhesion layer is coated on a silicon-on-insulator or the sacrificial material residing on a substrate.

In step 5202, nanoimprint lithography (or other type of lithography) is performed.

In step 5203, a polymer descum is performed.

In step 5204, a deep silicon etching with a VLS-optimized catalyst is performed.

In step 5205, a residue/resist cleaning are performed.

In step 5206, a VLS/VS of functional material (e.g., boron) is performed.

In step 5207, the back-side of the hard mask is etched.

In step 5208, a back-side lithography is performed.

In step 5209, a back-side etch of the silicon-on-insulator or the substrate with sacrificial material is performed.

In step 5210, final characterization and process optimization are performed.

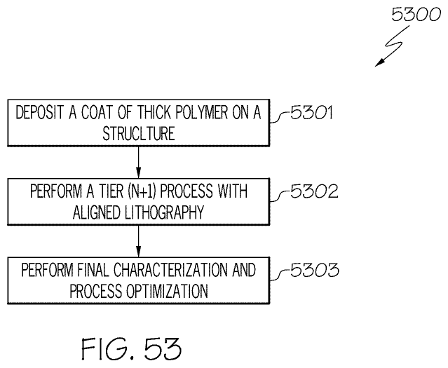

FIG. 53 is a flowchart of a method 5300 for a multi-tier process in accordance with an embodiment of the present disclosure.

In step 5301, a coat of thick polymer is deposited on a structure.

In step 5302, a tier (N+1) process with aligned lithography is performed.

In step 5303, final characterization and process optimization are performed.

As a result of the foregoing, the embodiments of the present disclosure provide tools and processes for utilizing electrochemical etching in creating arbitrary high aspect ratio nanostructures in a variety of substrates, such as silicon, aluminum oxide, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for fabricating high aspect ratio nanostructures in arbitrary functional materials, the method comprising:
depositing an (N+1)^{th} layer of substrate material on top of existing N layers of nanostructures, wherein N is a natural number;
patterning and etching in the (N+1)^{th} layer of the substrate material to create complementary nanostructures in the substrate material;
performing a conformal coating of gap-fill materials, encapsulation layers, and functional material on the complementary nanostructures to create functional material nanostructures in the (N+1)^{th} layer; and
performing a set of selective etches on the substrate material leaving behind multi-layered high aspect ratio nanostructures in the functional material.

2. The method as recited in claim 1, wherein a total height of the multi-layered high aspect ratio nanostructures is larger than one of the following: 10 μm, 20 μm. 50 μm, 100 μm, 200 μm, and 400 μm.

3. The method as recited in claim 1, wherein a feature pitch of the multi-layered high aspect ratio nanostructures is below one of the following: 500 nm, 200 nm, 100 nm, 50 nm, 20 nm, 10 nm, and 5 nm.

4. The method as recited in claim 1, wherein a final aspect ratio of the multi-layered high aspect ratio nanostructures is larger than one of the following: 10:1, 20:1, 50:1, 100:1, 200:1, 500:1, 1000:1, 2000:1, 5000:1, 10000:1, 50000:1, and 100000:1.

5. The method as recited in claim 1, wherein the N is larger than one of the following: 2, 5, 10, 20, 50, and 100.

6. The method as recited in claim 1, wherein the substrate material is one of or a combination of the following: silicon, a silicon containing material, silicon oxide, spin-on oxide, silicon carbide, silicon nitride, polycrystalline silicon, amorphous silicon, aluminum oxide, metal, a polymer, a spin-on polymer, carbon, a carbon containing material, a metalloid, boron, boron carbide, and boron nitride.

7. The method as recited in claim 1, wherein the patterning is one of the following: nanoimprint lithography, photolithography, electron-beam lithography, interference lithography, self-aligned nanopatterning techniques, nanosphere lithography, and displacement talbot lithography.

8. The method as recited in claim 1, wherein the etch is one of the following: MACE, Au MACE, Ru MACE, Pt MACE, vapor-phase MACE, liquid-phase MACE, reactive ion etching, and deep reactive ion etching.

9. The method as recited in claim 1, wherein the complementary nanostructures have one of the following cross-sections: circular, square with rounded edges, and polygonal with rounded edges.

10. The method as recited in claim 1, wherein the (N+1)^{th} layer of substrate material is deposited on top of existing N layers of nanostructures using one or more of the following methods: fusion bonding, direct bonding, hybrid bonding, anodic bonding, and covalent bonding.

11. The method as recited in claim 1, wherein the coating of the gap-fill materials, the encapsulation materials, and the functional material is performed using one or more of the following methods: spin-coating of a reflowable polymer, chemical vapor deposition, and a conformal coating process.

12. The method as recited in claim 1, wherein the gap-fill materials, the encapsulation materials, and the functional material comprise one or more of the following: silicon, a silicon containing material, silicon oxide, spin-on oxide, silicon carbide, silicon nitride, polycrystalline silicon, amorphous silicon, aluminum oxide, metal, a polymer, a spin-on polymer, carbon, a carbon containing material, a metalloid, boron, boron carbide, boron nitride, polymer-derived BN, polyborazylene, boron-hydride-based polymers, spin-on-glass, spin-on-carbon, spin-on-oxide, TiN, diamond, and CVD diamond.

13. The method as recited in claim 1, wherein the set of selective etches comprise one or more of the following: XeF₂ etch, fluoropolymer-based etch (utilizing CF₄, CHF₃), vapor HF, HF, plasma etch, wet etch, vapor-phase etch, crystallographic etch, KOH etch, DRIE, and RIE.

14. The method as recited in claim 1, wherein a sidewall slope near a tip of the complementary nanostructures or alternatively a step near the tip of the complementary nanostructures along with a planarization step after the coating of the functional material on the complementary nanostructures is used to create lateral tethers in the functional material.

15. The method as recited in claim 14, wherein the lateral tethers improve structural stability of the multi-layered high aspect ratio nanostructures.

16. The method as recited in claim 1, wherein the two or more of the depositing, the patterning and etching, the performing of the conformal coating and the performing of the set of selective etches are performed in a roll-to-roll manner.

17. The method as recited in claim 1 further comprising:
controlling or detecting nanostructure lateral dimension uniformity, nanostructure height uniformity, nanostructure yield, and/or nanostructure collapse with respect to the multi-layered high aspect ratio nanostructures.

18. The method as recited in claim 1, wherein the functional material nanostructures in the (N+1)^{th} layer are fabricated on top of existing N layers and aligned to one or more of the existing N layers during the patterning in the (N+1)^{th} layer.
